(19) United States
(12) Patent Application Publication
(10) Pub. No.: US 2026/0033080 A1
(43) Pub. Date: Jan. 29, 2026

(54) DISPLAY DEVICE

(71) Applicant: LG Display Co., Ltd., Seoul (KR)

(72) Inventors: Yuseung CHO, Suwon-si (KR); Sunghyun JANG, Paju-si (KR); Eunmin JO, Paju-si (KR)

(73) Assignee: LG Display Co., Ltd., Seoul (KR)

(21) Appl. No.: 19/252,619

(22) Filed: Jun. 27, 2025

(30) Foreign Application Priority Data
Jul. 25, 2024 (KR) 10-2024-0098875

(51) Int. Cl. H10H 29/49; H10H 29/855

(52) U.S. Cl. CPC H10H 29/49; H10H 29/8552

(57) ABSTRACT

A display device includes a micro light-emitting element. In an example, the display device includes a substrate including a display area and a non-display area, a driving chip disposed on the substrate in the display area, light-emitting elements electrically connected to the driving chip where the light-emitting elements and the driving chip are disposed in different layers in the display area, a pad electrode disposed in the non-display area of the substrate and electrically connected to the light-emitting elements, and a black matrix having a plurality of openings. An electric field is applied to each of the light-emitting elements in a non-contact manner to determine whether a current therefrom is detected through the pad electrode. Then the opening corresponding to the light-emitting element from which no current is detected through the pad electrode can be filled with the black matrix.

### CROSS-REFERENCE TO RELATED APPLICATION

This application claims priority to Korean Patent Application No. 10-2024-0098875, filed on Jul. 25, 2024 in the Korean Intellectual Property Office, and all the benefits accruing therefrom under 35 U.S.C. § 119, the contents of which in its entirety are herein expressly incorporated by reference into the present application.

### BACKGROUND

### Field

The present disclosure relates to a display device.

### Discussion of the Related Art

Display devices are applied to various electronic devices such as TV, mobile phones, laptops, and tablets.

The display device includes an organic light-emitting display device (OLED) that emits light by itself, and a liquid crystal display device (LCD) that requires a separate light source.

Recently, a display device including a light-emitting diode (LED) has attracted attention as a next-generation display device. Since the light-emitting diode is made of an inorganic material rather than an organic material, the display device including the light-emitting diode can have a faster lighting speed than that of the liquid crystal display device or the organic light-emitting display device, and can have excellent luminous efficiency, and can display an image with high luminance.

### SUMMARY OF THE DISCLOSURE

When a light-emitting element is transferred to a panel substrate, a main light-emitting element and a redundant light-emitting element for each of light-emitting elements are transferred to the panel substrate. For example, two light-emitting elements (e.g., main and redundant) for each of the light-emitting elements are transferred to the panel substrate.

In each light-emitting element, the redundant light-emitting element is not transferred to the panel substrate when the main light-emitting element operates normally. Thus, the material consumption of the light-emitting element can be reduced.

In order to meet the above-described needs, the inventors of the present application have invented a display device wherein only non-defective light-emitting elements are transferred to the panel substrate based a result of inspecting a light-emitting state of each of the light-emitting elements in a non-contact manner during a transfer process of the light-emitting elements.

Thus, one technical purpose of embodiments of the present disclosure is to provide a display device in which a main light-emitting element operating normally is transferred to the panel substrate during a transfer process of the light-emitting element, based on a result of inspecting a light-emitting state thereof in a non-contact manner, while a redundant light-emitting element corresponding thereto is transferred to the panel substrate only when the main light-emitting element is detected to be defective, based on a result of inspecting a light-emitting state thereof in a non-contact manner.

Another technical purpose of embodiments of the present disclosure is to provide a display device capable of reducing the material consumption for the light-emitting elements.

Still another technical purpose of an embodiment of the present disclosure is to provide a display device capable of reducing the non-transfer percentage of the light-emitting element.

Still yet another technical purpose of the present disclosure is to provide a display device capable of accurately transferring a light-emitting element onto to a target position of a panel substrate in a transfer process.

Still yet another technical purpose of the present disclosure is to provide a display device capable of improving a speed of a transfer process.

Still yet another technical purpose of the present disclosure is to provide a display device capable of improving product yield and productivity.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to embodiments of the present disclosure can include a substrate including a display area and a non-display area; a driving chip disposed on the display area of the substrate; a plurality of light-emitting elements electrically connected to the driving chip, wherein the plurality of light-emitting elements and the driving chip are disposed in different layers on the display area; a pad electrode disposed on the non-display area of the substrate and electrically connected to the plurality of light-emitting elements; and a black matrix having a plurality of openings defined therein respectively at positions corresponding to the plurality of light-emitting elements, wherein the black matrix is disposed on the plurality of light-emitting elements such that the plurality of light-emitting elements are exposed through the plurality of openings, respectively, wherein an electric field is applied to each of the plurality of light-emitting elements in a non-contact manner to determine whether a current therefrom is detected through the pad electrode, wherein the opening corresponding to the light-emitting element from which no current is detected through the pad electrode is filled with the black matrix.

A display device according to embodiments of the present disclosure can include a substrate including a display area and a non-display area; a driving chip disposed on the display area of the substrate; a plurality of light-emitting elements electrically connected to the driving chip, wherein the plurality of light-emitting elements are disposed on top of the driving chip in the display area; a pad electrode disposed on the non-display area of the substrate and electrically connected to the plurality of light-emitting elements; and an optical insulating layer disposed on the display area of the substrate so as to surround each of the plurality of light-emitting elements, wherein the optical insulating layer are further disposed on top of the plurality of light-emitting elements; and a black matrix disposed on the optical insulating layer and having a plurality of openings defined therein respectively at positions corresponding to the plurality of light-emitting elements, wherein an electric field is applied to each of the plurality of light-emitting elements in a non-contact manner to determine whether a current therefrom is detected through the pad electrode, wherein the opening corresponding to the light-emitting element from which no current is detected through the pad electrode is filled with the black matrix.

According to an embodiment of the present disclosure, the operation state of each light-emitting element can be inspected in a non-contact manner in the transfer process of the light-emitting element.

In addition, according to an embodiment of the present disclosure, the main light-emitting element operating normally is transferred to the panel substrate during a transfer process of the light-emitting element, based on a result of inspecting a light-emitting state thereof in a non-contact manner, while a redundant light-emitting element corresponding thereto is transferred to the panel substrate only when the main light-emitting element is defective, based on a result of inspecting a light-emitting state thereof in a non-contact manner. Thus, the display device capable of reducing the material consumption for the light-emitting elements can be realized.

In addition, according to an embodiment of the present disclosure, the material consumption in the transfer process of the light-emitting element is reduced, thereby reducing the manufacturing cost.

In addition, according to an embodiment of the present disclosure, the speed of the transfer process can be improved.

In addition, according to an embodiment of the present disclosure, a defect of the display device can be reduced by removing the defective element in the transfer process of the light-emitting element.

In addition, according to an embodiment of the present disclosure, a deterioration in the lifespan of the display device can be prevented by reducing the defect of the display device.

In addition, according to an embodiment of the present disclosure, as the defect of the display device is reduced, the power consumption of the display device can be lowered.

In addition, according to an embodiment of the present disclosure, as the defect of the light-emitting element is reduced, a long-life and low power consuming display device can be realized.

In addition, in the display device according to the present disclosure, as the defect of the light-emitting element is reduced in the process of manufacturing the display panel, the reduction of a deterioration in the lifespan of the display panel and the improvement of the quality of the display device can be implemented.

In addition, in the display device according to the present disclosure, the light-emitting element can be stably transferred, thereby improving product quality and securing product reliability.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is an exploded perspective view of a display device according to one or more embodiments of the present disclosure.

FIG. 2 is a plan view of a display device according to an embodiment of the present disclosure.

FIG. 3 is an enlarged view of a display device according to an embodiment of the present disclosure.

FIG. 4 is a diagram illustrating a circuit structure according to an embodiment of the present disclosure.

FIG. 5 is a plan view of a display device according to an embodiment of the present disclosure.

FIG. 6 is a plan view of a display device according to an embodiment of the present disclosure.

FIG. 7 is a plan view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIGS. 10 to 13 are diagrams illustrating an apparatus to which a display device according to embodiments of the present disclosure is applied.

FIG. 14 is a plan view illustrating a test pad and a trimming line of a display device according to an embodiment of the present disclosure.

FIG. 15 is a cross-sectional view showing an example of an operation test during a manufacturing process of a light-emitting element according to an embodiment of the present disclosure.

FIG. 16 is a diagram illustrating an example of BM masking of a light-emitting element in a display device according to an embodiment of the present disclosure.

FIG. 17 is a plan view illustrating an arrangement example of a light-emitting element after the BM masking according to an embodiment of the present disclosure.

FIG. 18 is a cross-sectional view illustrating a cross-section of the light-emitting element of FIG. 17 taken along a cutting line I-I.

FIG. 19 is a plan view of a display device according to another embodiment of the present disclosure.

FIG. 20 is a plan view illustrating an area in which one pixel driving circuit among a plurality of pixel driving circuits of FIG. 19 is disposed.

FIG. 21 is a diagram illustrating a touch operation of a display device according to another embodiment of the present disclosure.

FIG. 22 illustrates an example signal waveform diagram when a display device according to an embodiment of the present disclosure operates.

FIG. 23 is an enlarged plan view illustrating an area 7 of FIG. 20 according to another embodiment of the present disclosure.

FIG. 24 is a cross-sectional view taken along a cutting line II-II of FIG. 23.

### DETAILED DESCRIPTION OF THE EMBODIMENTS

Advantages and features of the present disclosure, and a method of achieving the advantages and features will become apparent with reference to embodiments described below in detail together with the accompanying drawings. However, the present disclosure is not limited to the embodiments as disclosed under, but can be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims. A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements can modify the entire list of elements and may not modify the individual elements of the list. In interpretation of numerical values, an error or tolerance therein can occur even when there is no explicit description thereof. In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when a first element or layer is referred to as being “connected to”, or “coupled to” a second element or layer, the first element can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween. Further, as used herein, when a layer, film, area, plate, or the like is disposed “on” or “on a top” of another layer, film, area, plate, or the like, the former can directly contact the latter or still another layer, film, area, plate, or the like can be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former can directly contact the latter or still another layer, film, area, plate, or the like can be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated. When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations. The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. For example, unless otherwise stated or clear from the context, the expression that ‘x uses a or b’ means one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term can be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure can work functionally.

When a first component or layer is described as “contacting” or “overlapping” a second component or layer, it should be understood that the first component or layer can directly contact or overlap the second component or layer, or a third component or layer can be interposed between the first and second components or layers that can indirectly contact or overlap each other unless otherwise specified. Further, the term “can” fully encompasses all the meanings and coverages of the term “may” and vice versa.

Hereinafter, various embodiments of the present disclosure will be described in detail with reference to the accompanying drawings. All the components of each display device according to all embodiments of the present disclosure are operatively coupled and configured.

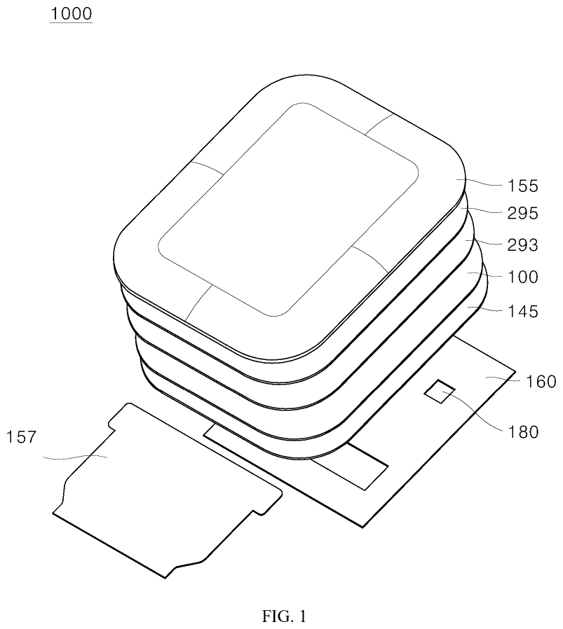

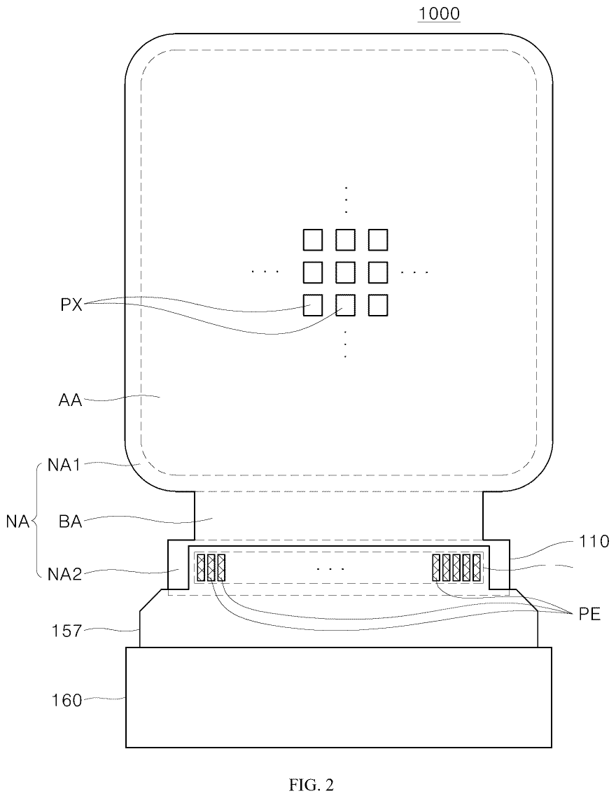

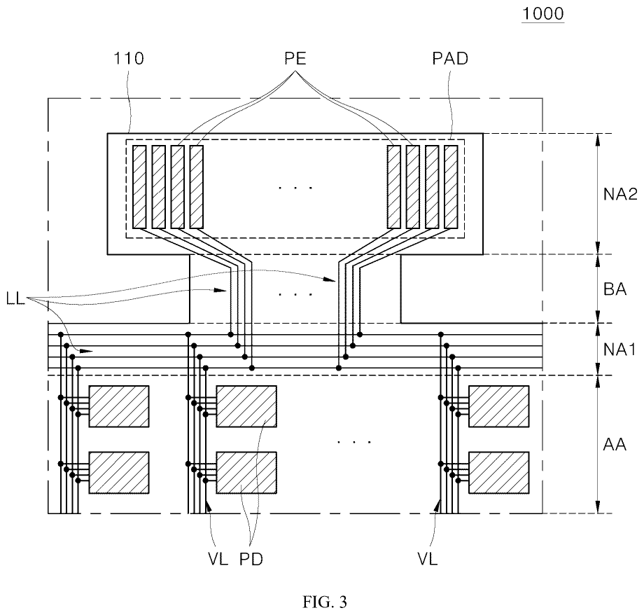

FIG. 1 is an exploded perspective view of a display device according to an embodiment of the present disclosure. FIG. 2 is a plan view of a display device according to an embodiment of the present disclosure. FIG. 3 is an enlarged view of a display device according to an embodiment of the present disclosure.

Referring to FIGS. 1 to 3, a display device 1000 according to an embodiment of the present disclosure can include a display panel 100, a polarizing layer 293, an adhesive layer 295, a cover member 155, a support substrate 145, a flexible circuit board 157, and a printed circuit board 160.

For example, the display device 1000 can include a substrate 110. The substrate 110 can be a member supporting other components of the display device 1000. The substrate 110 can be made of an insulating material. For example, the substrate 110 can be made of glass or resin. In addition, the substrate 110 can be made of a material having flexibility. For example, the substrate 110 can be made of a plastic material having flexibility, such as polyimide (PI). However, embodiments of the present disclosure are not limited thereto.

The display panel 100 can implement information, a video, and/or an image to be provided to a user. For example, the display panel 100 can include a display area AA (or active area) and a non-display area NA (or non-active area). For example, the substrate 110 can include the display area AA and the non-display area NA. The distinction between the display area AA and the non-display area NA is applied not only to the substrate 110 but also to the display device 1000.

The display area AA can be an area in which an image is displayed. The display area AA can include a plurality of pixels PX. Each of the plurality of pixels PX can be composed of a plurality of sub-pixels. A plurality of light-emitting elements can be disposed in each of the plurality of sub-pixels SP. A type of each of the plurality of light-emitting elements can vary according to a type of the display device 1000. For example, when the display device 1000 is an inorganic light-emitting display device, the light-emitting element can be a light-emitting diode (LED), a micro light-emitting diode (μLED), or a mini light-emitting diode (mini LED). However, embodiments of the present disclosure are not limited thereto.

The non-display area NA can be an area in which no image is displayed. Various lines and circuits for driving the plurality of pixels PX of the display area AA can be disposed in the non-display area NA. For example, various wires and driving circuits can be mounted in the non-display area NA, and a pad PAD to which an integrated circuit, a printed circuit, etc. are connected can be disposed in the non-display area NA. However, embodiments of the present disclosure are not limited thereto.

For example, the driving circuit can be a data driving circuit and/or a gate driving circuit. However, embodiments of the present disclosure are not limited thereto. Wires to which a control signal for controlling the driving circuits is supplied can be disposed. For example, the control signal can include various timing signals including a clock signal, an input data enable signal, and synchronization signals. However, embodiments of the present disclosure are not limited thereto. The control signal can be received via the pad PAD. For example, link lines LL for transmitting signals can be disposed in the non-display area NA. For example, driving components such as a flexible printed circuit board 157 and a printed circuit board 160 can be connected to the pad PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA is an area extending from at least one of a plurality of sides of the first non-display area NA1 and can be a bendable area. The second non-display area NA2 can be an area extending from the bending area BA, and the pad PAD can be disposed in the second non-display area. For example, the bending area BA can be in a bent state, and the remaining area of the substrate 110 except for the bending area BA can be in a flat state. In this case, as the bending area BA is bent, the second non-display area NA2 can be located on a rear surface of the display area AA. However, embodiments of the present disclosure are not limited thereto.

The display area AA of the substrate 110 or the display device 1000 can be formed in various shapes according to the designs of the display device 1000. For example, the display area AA can be formed in a rectangular shape having four corners of a round shape. However, embodiments of the present disclosure are not limited thereto. In another example, the display area AA can be formed in a rectangular shape in which four corners have a right angle or a circular shape. However, embodiments of the present disclosure are not limited thereto.

According to the present disclosure, a width of the second non-display area NA2 in which a plurality of pad electrodes PE are disposed can be greater than a width of the bending area BA in which only a plurality of link lines LL are disposed. In addition, the width of the display area AA in which the plurality of sub-pixels are disposed can be greater than the width of the bending area BA in which only the plurality of link lines LL are disposed. Although the width of the bending area BA is illustrated as being smaller than the width of the remaining area of the substrate 110 in the drawing, a shape of the substrate 110 including the bending area BA is merely an example, and embodiments of the present disclosure are not limited thereto.

Referring to FIG. 3, a plurality of pixel driving circuits PD can be disposed in the display area AA. The plurality of pixel driving circuits PD can be circuits for driving the light-emitting elements of the plurality of sub-pixels. Each of the plurality of pixel driving circuits PD can include a plurality of transistors including a driving transistor, a storage capacitor, etc., and can control an emission operation of the plurality of light-emitting elements by supplying a control signal, a power, and a driving current to the light-emitting elements of the plurality of sub-pixels. For example, the pixel driving circuit PD can include a power line and a signal line for controlling the emission on/off and/or emission time of the light-emitting element. For example, each of the plurality of pixel driving circuits PD can be a driver manufactured using a metal-oxide-silicon field effect transistor (MOSFET) manufacturing process and disposed on a semiconductor substrate. However, embodiments of the present disclosure are not limited thereto. A driver can include the plurality of pixel driving circuits PD and can drive the plurality of sub-pixels. For example, the plurality of pixel driving circuits PD can include a micro driver (μDriver). However, embodiments of the present disclosure are not limited thereto. For example, each of the plurality of pixel driving circuits PD can include a driving chip. However, embodiments of the present disclosure are not limited thereto. The micro driver can be implemented in a form of a chip.

Referring to FIG. 1 and FIG. 2, the flexible circuit board 157 and the printed circuit board 160 can be disposed under the display panel 100. The flexible circuit board 157 and the printed circuit board 160 can be disposed at least at one edge of the display panel 100. However, embodiments of the present disclosure are not limited thereto. One side of the flexible circuit board 157 can be attached to the display panel 100 and the other side thereof can be attached to the printed circuit board 160. However, embodiments of the present disclosure are not limited thereto. The flexible circuit board 157 can be a flexible film. However, embodiments of the present disclosure are not limited thereto.

The pad PAD including a plurality of pad electrodes PE can be disposed in the second non-display area NA2. A driving component including one or more flexible circuit boards (or flexible films) 157 and the printed circuit board 160 can be attached or bonded to the pad PAD. The plurality of pad electrodes PE of the pad PAD can be electrically connected to one or more flexible circuit boards (or flexible films) 157, and can transmit various signals (or power) from the printed circuit board 160 and the flexible circuit boards (or flexible films) 157 to the plurality of pixel driving circuits PD of the display area AA.

The flexible circuit board (or flexible film) 157 can be a film in which various components are disposed on a flexible base film. For example, a driving IC such as a gate driver IC or a data driver IC can be disposed on the flexible circuit board (or flexible film) 157. However, embodiments of the present disclosure are not limited thereto. The driving IC DT can be a component that processes data for displaying an image and a driving signal. The driving IC DT can be disposed in a manner such as a Chip On Glass (COG), a Chip On Film (COF), or a Tape Carrier Package (TCP) according to a mounted manner. However, embodiments of the present disclosure are not limited thereto. The flexible circuit board (or flexible film) 157 can be attached or bonded to the plurality of pad electrodes PE by a conductive adhesive layer. However, embodiments of the present disclosure are not limited thereto.

The printed circuit board 160 can be electrically connected to one or more flexible circuit boards (or flexible films) 157 and can be a component that supplies a signal to the driving IC. The printed circuit board 160 can be disposed on one side of the flexible circuit board (or flexible film) 157 so as to be electrically connected to the flexible circuit board (or flexible film) 157. Various components for supplying various signals to the driving IC can be disposed on the printed circuit board 160. For example, various components such as a timing controller, a power supply unit, a memory, or a processor can be disposed on the printed circuit board 160. For example, the printed circuit board 160 can include a power management integrated circuit (PMIC). However, embodiments of the present disclosure are not limited thereto.

The printed circuit board 160 can include at least one hole 180. However, embodiments of the present disclosure are not limited thereto. An internal component for sensing ambient light or temperature that can be provided to the plurality of sensors can be disposed in an area corresponding to the at least one hole 180. For example, the internal component can include an ALS (Ambient light sensor), a temperature sensor, etc. However, embodiments of the present disclosure are not limited thereto. For example, the hole 180 can be a transmission hole or the like. However, embodiments of the present disclosure are not limited thereto.

Referring to FIG. 1, the polarizing layer 293 can be disposed on the display panel 100. The polarizing layer 293 can prevent or reduce light generated from an external light source from entering the display panel 100 and thus affecting the light-emitting element or the like.

The cover member 155 can be disposed on the polarizing layer 293. The cover member 155 can be a member for protecting the display panel 100. The adhesive layer 295 can be disposed between the polarizing layer 293 and the cover member 155. The cover member 155 can be attached to the display panel 100 via the adhesive layer 295. The adhesive layer 295 can include an OCA (Optically clear adhesive), an OCR (Optically clear resin), a PSA (Pressure sensitive adhesive), etc. However, embodiments of the present disclosure are not limited thereto.

The support substrate 145 can be disposed between the display panel 100 and the printed circuit board 160. The support substrate 145 can reinforce the rigidity of the display panel 100. The support substrate 145 can be a back plate. However, embodiments of the present disclosure are not limited thereto.

Referring to FIGS. 1 to 3, the plurality of link lines LL can be disposed in the non-display area NA. The plurality of link lines LL can be lines for transmitting various signals from one or more flexible circuit boards (or flexible films) 157 and the printed circuit board 160 to the display area AA. The plurality of link lines LL can extend from the plurality of pad electrodes PE of the second non-display area NA2 toward the bending area BA and the first non-display area NA1 and can be electrically connected to the plurality of driving lines VL of the display area AA. The plurality of pixel driving circuits PD can be driven upon receiving signals from one or more flexible circuit boards (or flexible films) 157 and the printed circuit boards 160 via driving lines VL of the display area AA and the link lines LL of the non-display area NA.

For example, a plurality of driving lines VL together with the plurality of link lines LL can transmit signals output from the flexible circuit board (or flexible film) 157 and the printed circuit board 160 to the plurality of pixel driving circuits PD. The plurality of driving lines VL can be disposed in the display area AA and can be electrically connected to each of the plurality of pixel driving circuits PD. The plurality of driving lines VL can extend from the display area AA toward the non-display area NA and can be electrically connected to the plurality of link lines LL. Accordingly, the signals output from the flexible circuit board (or flexible film) 157 and the printed circuit board 160 can be transmitted to each of the plurality of pixel driving circuits PD via the plurality of link lines LL and the plurality of driving lines VL.

As the bending area BA is bent, a portion of each of the plurality of link lines LL can also be bent. Thus, stress is concentrated on a portion of the bent link line LL, and accordingly, a crack can occur in the link line LL. Accordingly, the plurality of link lines LL can be made of a conductive material having excellent ductility to reduce the cracks occurring when the bending area BA is bent. For example, the plurality of link lines LL can be made of a conductive material having excellent ductility, such as gold (Au), silver (Ag), aluminum (Al), etc. However, embodiments of the present disclosure are not limited thereto. In addition, the plurality of link lines LL can be made of one of various conductive materials used in the display area AA. For example, the plurality of link lines LL can be made of molybdenum (Mo), chromium (Cr), titanium (Ti), nickel (Ni), neodymium (Nd), copper (Cu), an alloy thereof, or an alloy of silver (Ag) and magnesium (Mg). However, embodiments of the present disclosure are not limited thereto. The plurality of link lines LL can be configured in a multilayer structure including various conductive materials. For example, the plurality of link lines LL can be configured in a triple layer structure of a titanium (Ti) layer/aluminum (Al) layer/titanium (Ti) layer. However, embodiments of the present disclosure are not limited thereto.

The plurality of link lines LL can be formed in various shapes to reduce the stress. At least a portion of each of the plurality of link lines LL disposed on the bending area BA can extend in the same direction as an extending direction of the bending area BA, or can extend in a direction different from the extending direction of the bending area BA to reduce the stress. For example, when the bending area BA extends in one direction from the first non-display area NA1 toward the second non-display area NA2, at least a portion of the link line LL disposed on the bending area BA can extend in a direction inclined with respect to the one direction. In another example, at least a portion of each of the plurality of link lines LL can be formed in each of patterns of various shapes. For example, at least a portion of each of the plurality of link lines LL disposed on the bending area BA can have a shape in which conductive patterns having at least one of a diamond shape, a rhombus shape, a trapezoidal shape, a triangular wave shape, a sawtooth wave shape, a sine wave shape, a circular shape, and an omega ((2) shape are repeatedly arranged. However, embodiments of the present disclosure are not limited thereto. Therefore, in order to minimize the stress concentrated on the plurality of link lines LL and the resulting crack, the shape of each of the plurality of link lines LL can be formed in various shapes including the above-described shape. However, embodiments of the present disclosure are not limited thereto.

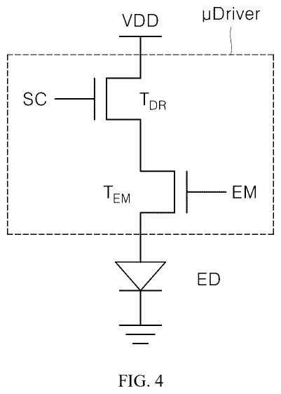

FIG. 4 is a diagram illustrating a circuit structure according to an embodiment of the present disclosure.

Particularly, FIG. 4 illustrates that one light-emitting element ED is connected to the micro driver μDriver. However, embodiments of the present disclosure are not limited thereto. For example, eight light-emitting elements ED can be simultaneously connected to one micro driver μDriver. In another example, 16 light-emitting elements ED can simultaneously be connected to one micro driver μDriver, or 32 light-emitting elements ED or 64 light-emitting elements ED can be simultaneously connected to one micro driver μDriver or 64 light-emitting elements ED or 256 light-emitting elements ED can be simultaneously connected to one micro driver μDriver or 768 light-emitting elements ED can be simultaneously connected to one micro driver μDriver. The light-emitting element ED can be a micro light-emitting element μLED.

Referring to FIG. 4, one micro driver μDriver can include a driving transistor T_{DR} and a light-emission transistor T_{EM}. However, embodiments of the present disclosure are not limited thereto.

For example, a high potential power voltage VDD can be applied to a first electrode of the driving transistor T_{DR}, a first electrode of the light-emission transistor T_{EM} can be connected to a second electrode of the driving transistor T_{DR}, and a scan signal SC can be applied to a gate electrode of the driving transistor T_{DR}. The scan signal SC applied to the gate electrode of the driving transistor T_{DR} is a direct current power, and a fixed reference voltage Vref can be applied thereto every frame. However, embodiments of the present disclosure are not limited thereto.

The second electrode of the driving transistor T_{DR} can be connected to the first electrode of the light-emission transistor T_{EM}, the light-emitting element ED can be connected to a second electrode of the light-emission transistor T_{EM}, and the light-emission signal EM can be applied to a gate electrode of the light-emission transistor T_{EM}. The light-emission signal EM applied to the gate electrode of the light-emission transistor T_{EM} can be a pulse width modulation signal that varies in every frame. However, embodiments of the present disclosure are not limited thereto.

The light-emitting element ED can have a first electrode connected to the second electrode of the light-emission transistor T_{EM}, and a second electrode connected to the ground. For example, the first electrode thereof can be an anode electrode, and the second electrode thereof can be a cathode electrode. However, embodiments of the present disclosure are not limited thereto.

Each of the driving transistor T_{DR} and the light-emission transistor T_{EM} can be an n-type transistor or a p-type transistor.

In the micro driver μDriver, the driving transistor T_{DR} can be turned on based on the scan signal SC applied thereto from a timing controller T-CON, and the light-emission transistor T_{EM} can be turned on based on the light-emission signal EM. Accordingly, the driving current is applied to the light-emitting element ED via the driving transistor T_{DR} and the light-emission transistor T_{EM} based on the high potential power voltage VDD applied to the first electrode of the driving transistor T_{DR}, so that the light-emitting element ED can emit light.

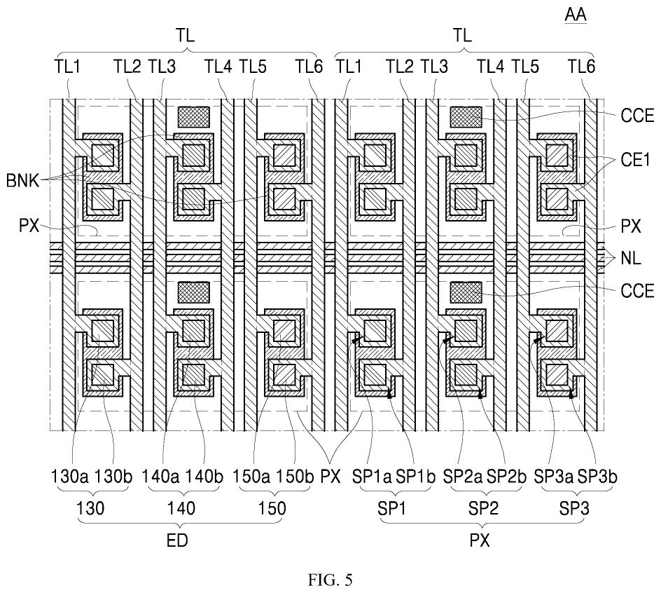

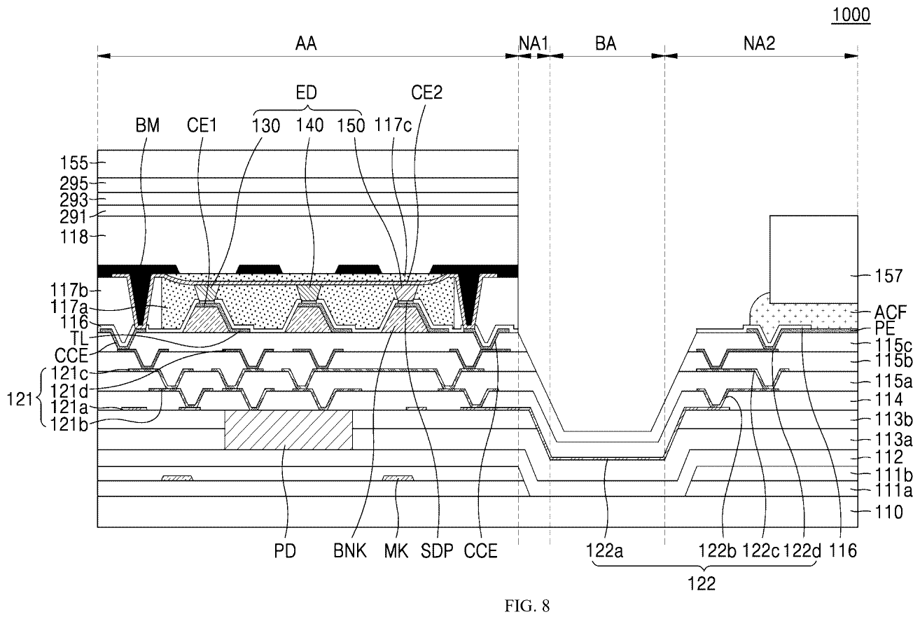

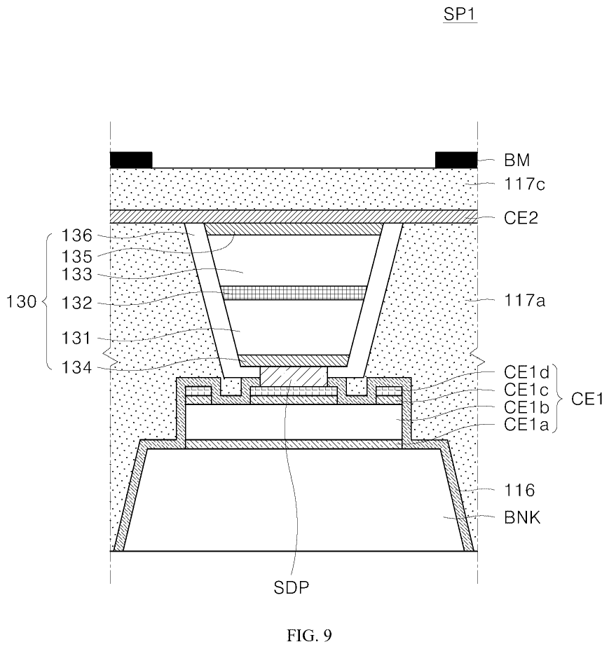

FIGS. 5 to 7 are plan views of a display device according to an embodiment of the present disclosure. FIGS. 8 and 9 are cross-sectional views of a display device according to an embodiment of the present disclosure.

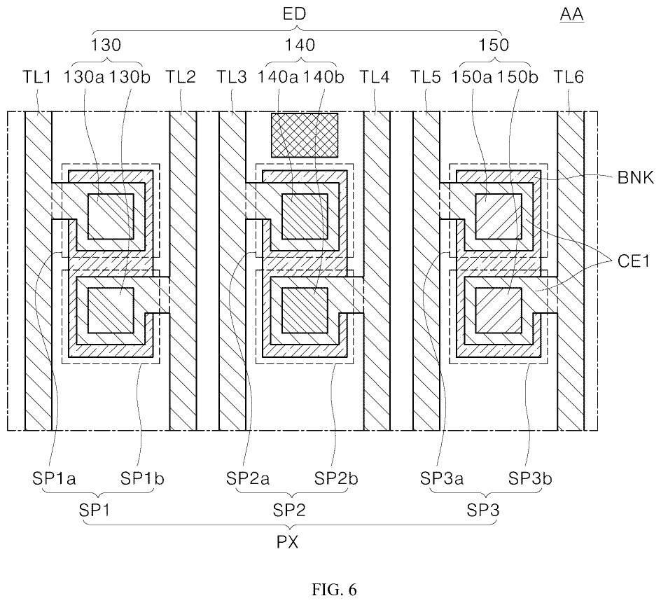

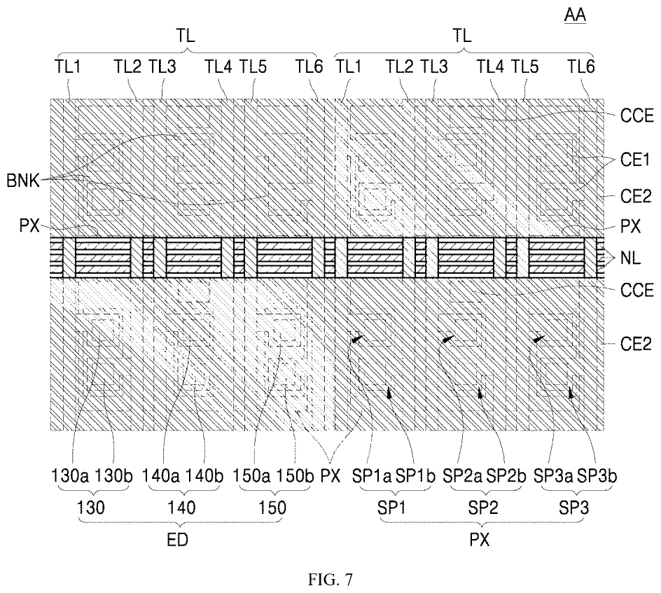

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA1, the bending area BA, and the second non-display area NA2. For example, FIG. 9 is a cross-sectional view of a display area including one sub-pixel SP1. FIGS. 5 and 6 illustrate a plurality of signal lines TL, a plurality of communication lines NL, a plurality of first electrodes CE1, a plurality of banks BNK, and a plurality of light-emitting elements ED. However, embodiments of the present disclosure are not limited thereto. FIG. 7 is an enlarged plan view in which a plurality of second electrodes CE2 are additionally disposed in FIG. 5.

Referring to FIGS. 5, 6, and 9, a plurality of pixels PX, each including a plurality of sub-pixels, can be disposed in the display area AA. Each of the plurality of sub-pixels includes a light-emitting element ED, and can independently emit light. The plurality of sub-pixels can be arranged in a plurality of rows and a plurality of columns and thus can be arranged in a matrix form. However, embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2, and the third sub-pixel SP3 can be a red sub-pixel, another thereof can be a green sub-pixel, and the other thereof can be a blue sub-pixel. A type of each of the plurality of sub-pixels is an example, and embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can include a (1-1)-th sub-pixel SP1a and a (1-2)-th sub-pixel SP1b. The pair of second sub-pixels SP2 can include a (2-1)-th sub-pixel SP2a and a (2-2)-th sub-pixel SP2b. The pair of third sub-pixels SP3 can include a (3-1)-th sub-pixel SP3a and a (3-2)-th sub-pixel SP3b. For example, one pixel PX can include a (1-1)-th sub-pixel SP1a and a (1-2)-th sub-pixel SP1b, a (2-1)-th sub-pixel SP2a and a (2-2)-th sub-pixel SP2b, and a (3-1)-th sub-pixel SP3a and a (3-2)-th sub-pixel SP3b. However, embodiments of the present disclosure are not limited thereto.

The plurality of sub-pixels constituting one pixel PX can be arranged in various manner. In one example, in one pixel PX, a pair of first sub-pixels SP1 can be arranged in the same column, a pair of second sub-pixels SP2 can be arranged in the same column, and a pair of third sub-pixels SP3 can be arranged in the same column. The first sub-pixel SP1, the second sub-pixel SP2, and the third sub-pixel SP3 can be arranged in the same row. The number and arrangement of the plurality of sub-pixels constituting one pixel PX are examples, and embodiments of the present disclosure are not limited thereto.

A plurality of signal lines TL can be disposed in an area between adjacent ones of the plurality of sub-pixels. The plurality of signal lines TL can extend in the column direction while being disposed between adjacent ones of the plurality of sub-pixels. The plurality of signal lines TL can be lines for transmitting an anode voltage from the pixel driving circuit PD to the plurality of sub-pixels. For example, the plurality of signal lines TL can be electrically connected to the plurality of pixel driving circuits PD and the first electrodes CE1 of the plurality of sub-pixels. The anode voltage output from the pixel driving circuit PD can be transmitted to the first electrodes CE1 of the plurality of sub-pixels via the plurality of signal lines TL. For example, the first electrode CE1 can be an electrode electrically connected to the anode electrode 134 of the light-emitting element ED. Accordingly, the anode voltage from the signal line TL can be transmitted to the anode electrode 134 of the light-emitting element ED via the first electrode CE1.

Therefore, a structure of the display device 1000 can be simplified using the pixel driving circuit PD in which the plurality of pixel circuits are integrated with each other, instead of forming a plurality of transistors and a storage capacitor in each of the plurality of sub-pixels. In addition, as circuits respectively disposed in the plurality of sub-pixels are integrated into one pixel driving circuit PD, high-efficiency low-power operation of the display device can be achieved.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to the pair of first sub-pixels SP1, respectively. The third signal line TL3 and the fourth signal line TLA can be electrically connected to the pair of second sub-pixels SP2, respectively. The fifth signal line TL5 and the sixth signal line TL6 can be electrically connected to the pair of third sub-pixels SP3, respectively.

The first signal line TL1 can be disposed on one side of the pair of first sub-pixels SP1, and the second signal line TL2 can be disposed on the other side of the pair of first sub-pixels SP1. The first signal line TL1 can be electrically connected to one first sub-pixel SP1 of the pair of first sub-pixels SP1, for example, the first electrode CE1 of the (1-1)-th sub-pixel SP1a. The second signal line TL2 can be electrically connected to the other first sub-pixel SP1 of the pair of first sub-pixels SP1, for example, the first electrode CE1 of the (1-2)-th sub-pixel SP1b.

The third signal line TL3 can be disposed on one side of the pair of second sub-pixels SP2, and the fourth signal line TL4 can be disposed on the other side of the pair of second sub-pixels SP2. For example, the third signal line TL3 can be disposed adjacent to the second signal line TL2. The third signal line TL3 can be electrically connected to one second sub-pixel SP2 of the pair of second sub-pixels SP2, for example, the first electrode CE1 of the (2-1)-th sub-pixel SP2a. The fourth signal line TL4 can be electrically connected to the other second sub-pixel SP2 of the pair of second sub-pixels SP2, for example, the first electrode CE1 of the (2-2)-th sub-pixel SP2b.

The fifth signal line TL5 can be disposed on one side of the pair of third sub-pixels SP3, and a sixth signal line TL6 can be disposed on the other side of the pair of third sub-pixels SP3. For example, the fifth signal line TL5 can be disposed adjacent to the fourth signal line TL4. The sixth signal line TL6 can be disposed adjacent to the first signal line TL1 connected to the pixel PX adjacent thereto. The fifth signal line TL5 can be electrically connected to one third sub-pixel SP3 of the pair of third sub-pixels SP3, for example, the first electrode CE1 of the (3-1)-th sub-pixel SP3a. The sixth signal line TL6 can be electrically connected to the other third sub-pixel SP3 of the pair of third sub-pixels SP3, for example, the first electrode CE1 of the (3-2)-th sub-pixel SP3b.

Each of the plurality of signal lines TL can be made of a conductive material. For example, each of the plurality of signal lines TL can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, each of the plurality of signal lines TL can have a multilayer structure made of a conductive material. For example, each of the plurality of signal lines TL can have a multilayer structure of a titanium (Ti) layer/aluminum (Al) layer/titanium (Ti) layer/indium tin oxide (ITO) layer. However, embodiments of the present disclosure are not limited thereto.

A plurality of communication lines NL can be disposed in an area between adjacent ones of the plurality of pixels PX. The plurality of communication lines NL can extend in the row direction while being disposed in an area between adjacent ones of the plurality of pixels PX. The plurality of communication lines NL can be disposed in an area between adjacent ones of the plurality of second electrodes CE2 and may not overlap the plurality of second electrodes CE2. For example, the plurality of communication lines NL can be lines used for short-range communication such as near field communication (NFC). The plurality of communication lines NL can function as antennas. For example, the plurality of communication lines NL can be a plurality of connection lines, etc. However, embodiments of the present disclosure are not limited thereto.

According to the present disclosure, a bank BNK can be disposed in each of the plurality of sub-pixels. Each of the plurality of banks BNK can be a structure in which each of the plurality of light-emitting elements ED is seated. The plurality of banks BNK can guide positions of the plurality of light-emitting elements ED in a transfer process of transferring the plurality of light-emitting elements ED to the substrate, respectively. In the transfer process of the plurality of light-emitting elements ED thereto, the plurality of light-emitting elements ED can be transferred onto the plurality of banks BNK, respectively. The plurality of banks BNK can be bank patterns, structures, etc. However, embodiments of the present disclosure are not limited thereto.

The bank BNK of the first sub-pixel SP1, the bank BNK of the second sub-pixel SP2, and the bank BNK of the third sub-pixel SP3 can be spaced apart from each other. The bank BNK of the first sub-pixel SP1, the bank BNK of the second sub-pixel SP2, and the bank BNK of the third sub-pixel SP3 can be constructed to be isolated from each other. Accordingly, the banks BNK of the first sub-pixel SP1, the second sub-pixel SP2, and the third sub-pixel SP3 to which different types of light-emitting elements ED are transferred, respectively can be easily identified.

The bank BNK of the (1-1)-th sub-pixel SP1a and the bank BNK of the (1-2)-th sub-pixel SP1b can be connected to each other, or can be spaced apart or isolated from each other. For example, the bank BNK of the (1-1)-th sub-pixel SP1a and the bank BNK of the (1-2)-th sub-pixel SP1b in which the light-emitting elements ED of the same type are disposed, respectively can be connected to each other, or can be spaced apart or isolated from each other in consideration of a design such as a transfer process requirement. In addition, the bank BNK of the (2-1)-th sub-pixel SP2a and the bank BNK of the (2-2)-th sub-pixel SP2b can be connected to each other, or can be spaced apart or isolated from each other. The bank BNK of the (3-1)-th sub-pixel SP3a and the bank BNK of the (3-2)-th sub-pixel SP3b can be connected to each other, or can be spaced apart or isolated from each other. Accordingly, the banks BNK of the pair of first sub-pixels SP1, the banks BNK of the pair of second sub-pixels SP2, and the banks BNK of the pair of third sub-pixels SP3 can be variously formed. Embodiments of the present disclosure are not limited thereto.

For example, each of the plurality of banks BNK can be made of an organic insulating material. Each of the plurality of banks BNK can be formed as a single layer or multiple layers made of an organic insulating material. For example, each of the plurality of banks BNK can be made of photoresist, polyimide (PI), or an acryl-based material. However, embodiments of the present disclosure are not limited thereto.

The first electrode CE1 can be disposed in each of the plurality of sub-pixels SP. The first electrode CE1 can be disposed on the bank BNK. The first electrode CE1 can be electrically connected to one signal line TL among the plurality of signal lines TL. At least a portion of the first electrode CE1 can extend outwardly of the bank BNK and can be electrically connected to the signal line TL closest to the first electrode CE1. For example, a portion of the first electrode CE1 of the (1-1)-th sub-pixel SP1a can extend to one side area of the (1-1)-th sub-pixel SP1a so as to be electrically connected to the first signal line TL1, and a portion of the first electrode CE1 of the (1-2)-th sub-pixel SP1b can extend to the other side area of the (1-2)-th sub-pixel SP1b so as to be electrically connected to the second signal line TL2. A portion of the first electrode CE1 of the (2-1)-th sub-pixel SP2a can extend to one side area of the (2-1)-th sub-pixel SP2a so as to be electrically connected to the third signal line TL3, and a portion of the first electrode CE1 of the (2-1)-th sub-pixel SP2b can extend to the other side area of the (2-1)-th sub-pixel SP2b so as to be electrically connected to the fourth signal line TL4. A portion of the first electrode CE1 of the (3-1)-th sub-pixel SP3a can extend to one side area of the (3-1)-th sub-pixel SP3a so as to be electrically connected to the fifth signal line TL5, and a portion of the first electrode CE1 of the (3-2)-th sub-pixel SP3b can extend to the other side area of the (3-2)-th sub-pixel SP3b so as to be electrically connected to the sixth signal line TL6.

The first electrode CE1 can be electrically connected to the anode electrode 134 of the light-emitting element ED, and can transmit an anode voltage from the pixel driving circuit PD to the light-emitting element ED via the signal line TL. Different voltages can be respectively applied to the first electrodes CE1 of the plurality of sub-pixels based on a displayed image. For example, different voltages can be applied to the first electrodes CE1 of the plurality of sub-pixels SP, respectively. Accordingly, the first electrode CE1 can be a pixel electrode, and embodiments of the present disclosure are not limited thereto.

The first electrode CE1 can be made of a conductive material. For example, the first electrode CE1 can be integrally formed with the plurality of signal lines TL. For example, the first electrode CE1 can be made of the same conductive material as that of each of the plurality of signal lines TL. However, embodiments of the present disclosure are not limited thereto. For example, the first electrode CE1 can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, the first electrode CE1 can be configured to have a multilayer structure made of a conductive material. For example, each of the plurality of first electrodes CE1 can have a multilayer structure of a titanium (Ti) layer/aluminum (Al) layer/titanium (Ti) layer/indium tin oxide (ITO) layer. However, embodiments of the present disclosure are not limited thereto.

The light-emitting element ED can be disposed in each of the plurality of sub-pixels. The plurality of light-emitting elements ED can be one of a light-emitting diode (LED) or a micro light-emitting diode (μLED). However, embodiments of the present disclosure are not limited thereto. The plurality of light-emitting elements ED can be disposed on the bank BNK and the first electrode CE1. The plurality of light-emitting elements ED can be disposed on the first electrode CE1 and can be electrically connected to the first electrode CE1. Accordingly, the light-emitting element ED can receive the anode voltage from the pixel driving circuit PD via the signal line TL and the first electrode CE1 to emit light.

The plurality of light-emitting elements ED can include a first light-emitting element 130, a second light-emitting element 140, and a third light-emitting element 150. The first light-emitting element 130 can be disposed in the first sub-pixel SP1. The second light-emitting element 140 can be disposed in the second sub-pixel SP2. The third light-emitting element 150 can be disposed in the third sub-pixel SP3. For example, one of the first light-emitting element 130, the second light-emitting element 140, and the third light-emitting element 150 can be a red light-emitting element, another thereof can be a green light-emitting element, and the other thereof can be a blue light-emitting element. However, embodiments of the present disclosure are not limited thereto. Accordingly, various colors of light including white can be implemented by combining red light, green light, and blue light respectively emitted from the plurality of light-emitting elements ED from each other. The type of each of the plurality of light-emitting elements ED is merely an example, and embodiments of the present disclosure are not limited thereto.

The first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-1)-th light-emitting element 140b disposed in the (2-1)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b.

Referring to FIGS. 5 and 6, and FIGS. 7 and 9 together, the second electrode CE2 can be disposed in each of the plurality of sub-pixels SP. The second electrode CE2 can be disposed on the light-emitting element ED. The second electrode CE2 can be electrically connected to the pixel driving circuit PD via a plurality of contact electrodes CCE.

For example, the second electrode CE2 can be electrically connected to the cathode electrode 135 of the light-emitting element ED to transmit the cathode voltage from the pixel driving circuit PD to the light-emitting element ED. The same cathode voltage can be applied to the second electrodes CE2 of the plurality of sub-pixels SP. For example, the same voltage can be applied to the second electrodes CE2 of the plurality of sub-pixels and the cathode electrode 135 of the light-emitting element ED. Accordingly, the second electrode CE2 can be a common electrode. However, embodiments of the present disclosure are not limited thereto.

At least some of the plurality of sub-pixels can share the second electrode CE2 with each other. At least some of the second electrodes CE2 of the plurality of sub-pixels SP can be electrically connected to each other. As the same voltage is applied to the second electrodes CE2, the second electrode CE2 can be shared by the at least some sub-pixels. For example, the second electrodes CE2 of at least some pixels PX among the plurality of pixels PX disposed in the same row can be connected to each other. For example, one second electrode CE2 can be disposed in the plurality of pixels PX. One second electrode CE2 can be disposed in a combination of n sub-pixels.

For example, some of the respective second electrodes CE2 of the plurality of sub-pixels SP can be spaced apart or isolated from each other. For example, the second electrode CE2 connected to the pixels PX of an n-th row and the second electrode CE2 connected to the pixels PX of an (n+1)-th row can be spaced apart or isolated from each other. For example, adjacent ones of the plurality of second electrodes CE2 can be arranged to be spaced apart from each other while the plurality of communication lines NL extending in the row direction are disposed therebetween. Accordingly, the number of the plurality of sub-pixels can be greater than the number of the plurality of second electrodes CE2. In another example, all of the second electrodes CE2 of the plurality of sub-pixels can be connected to each other, such that only one second electrode CE2 can be disposed on the substrate 110. However, embodiments of the present disclosure are not limited thereto.

Each of the plurality of second electrodes CE2 can be made of a transparent conductive material. However, embodiments of the present disclosure are not limited thereto. Each of the plurality of second electrodes CE2 can be made of a transparent conductive material, and can allow light emitted from the light-emitting element ED to be directed upwardly of the second electrode CE2. For example, the second electrode CE2 can be made of a transparent conductive material such as Indium Tin Oxide (ITO), Indium Zinc Oxide (IZO), Indium Gallium Zinc Oxide (IGZO), etc. However, embodiments of the present disclosure are not limited thereto.

The plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap the plurality of contact electrodes CCE.

For example, each of the plurality of contact electrodes CCE can be electrically connected to each of the plurality of second electrodes CE2. Each of the plurality of contact electrodes CCE can be disposed between the substrate 110 and each of the plurality of second electrodes CE2 to transmit the cathode voltage from the pixel driving circuit PD to each of the second electrodes CE2.

For example, when the micro LED is used as the light-emitting element ED, a plurality of micro LEDs can be formed on a wafer, and the micro LEDs can be transferred to the substrate 110 of the display device 1000 to manufacture the display device 1000. Various defects can occur in the process of transferring the plurality of light-emitting elements ED having a fine size from the wafer to the substrate 110. For example, a non-transfer defect in which the light-emitting element ED is not transferred can occur in some sub-pixels, and an incorrect position defect in which the light-emitting element ED is transferred out of the correct position due to an alignment error can occur in some further sub-pixels. In addition, the transfer process is normally performed, while the transferred light-emitting element ED itself can be defective. Therefore, the plurality of light-emitting elements ED of the same type can be transferred to one sub-pixel in consideration of the defect in the transfer process of the plurality of light-emitting elements ED. The lighting test of the plurality of light-emitting elements ED is performed, and only one light-emitting element ED that has been finally determined to be normal or non-defective can be used.

For example, both the (1-1)-th light-emitting element 130a and the (1-2)-th light-emitting element 130b can be transferred to one pixel PX at the same time, and whether they are defective can be inspected. When both the (1-1)-th light-emitting element 130a and the (1-2)-th light-emitting element 130b are determined to be normal or non-defective, only the (1-1)-th light-emitting element 130a can be used, and the (1-2)-th light-emitting element 130b may not be used. In another example, when only the (1-2)-th light-emitting element 130b among the (1-1)-th light-emitting element 130a and the (1-2)-th light-emitting element 130b is determined to be normal or non-defective, the (1-1)-th light-emitting element 130a may not be used and only the (1-2)-th light-emitting element 130b can be used. Therefore, even when the plurality of light-emitting elements ED of the same type are transferred to one pixel PX, only one light-emitting element ED can be finally used.

Accordingly, one of the pair of light-emitting elements ED can act as a main (primary) light-emitting element ED, and the other of the pair of light-emitting elements ED can act as a redundant light-emitting element ED. The redundant light-emitting element ED can be an extra light-emitting element ED that is transferred in preparation for the defect of the main light-emitting element ED. When the main light-emitting element ED is defective, the main light-emitting element ED can be replaced with the redundant light-emitting element ED. Accordingly, both the main light-emitting element ED and the redundant light-emitting element ED are transferred to one pixel PX at the same time, thereby minimizing a decrease in display quality due to the defect of the main light-emitting element ED and the redundant light-emitting element ED.

For example, each of the (1-1)-th light-emitting element 130a, the (2-1)-th light-emitting element 140a, and the (3-1)-th light-emitting element 150a transferred to one pixel PX can be used as the main light-emitting element ED, while each of the (1-2)-th light-emitting element 130b, the (2-2)-th light-emitting element 140b, and the (3-2)-th light-emitting element 150b can be used as the redundant light-emitting element ED.

FIG. 8 is a cross-sectional view of a display device according to an embodiment of the present disclosure. FIG. 9 is a cross-sectional view of a display device according to an embodiment of the present disclosure. For example, FIG. 8 is a cross-sectional view of the display area AA, the first non-display area NA1, the bending area BA, and the second non-display area NA2. For example, FIG. 9 is a cross-sectional view of a display area including one sub-pixel SP1.

Referring to FIG. 8, a first buffer layer 111a and a second buffer layer 111b can be disposed on the remaining area of the substrate 110 except for the bending area BA.

The first buffer layer 111a and the second buffer layer 111b can be disposed in the display area AA, the first non-display area NA1, and the second non-display area NA2. The first buffer layer 111a and the second buffer layer 111b can reduce invasion of moisture or impurities through the substrate 110. Each of the first buffer layer 111a and the second buffer layer 111b can be made of an inorganic insulating material. For example, each of the first buffer layer 111a and the second buffer layer 111b can be formed as a single layer or multiple layers made of silicon oxide (SiOx) or silicon nitride (SiNx). However, embodiments of the present disclosure are not limited thereto.

For example, a portion of each of the first buffer layer 111a and the second buffer layer 111b in the bending area BA can be removed. An upper surface of a portion of the substrate 110 located in the bending area BA can be not covered with the first buffer layer 111a and the second buffer layer 111b so as to be exposed. Removing the portion of each of the first buffer layer 111a and the second buffer layer 111b made of the inorganic insulating material as disposed in the bending area BA can allow cracks of the first buffer layer 111a and the second buffer layer 111b that can occur during bending to be minimized.

A plurality of alignment keys MK can be disposed between the first buffer layer 111a and the second buffer layer 111b. The plurality of alignment keys MK can be configured to identify the position of the pixel driving circuit PD during the manufacturing process of the display device 1000. For example, the plurality of alignment keys MK can be configured to correctly align the positions of the pixel driving circuits PD transferred onto the adhesive layer 112. In another example, the plurality of alignment keys MK can be omitted.

The adhesive layer 112 can be disposed on the second buffer layer 111b. The adhesive layer 112 can be disposed in the display area AA, the first non-display area NA1, the bending area BA, and the second non-display area NA2. In another example, at least a portion of the adhesive layer 112 can be removed in the non-display area NA including the bending area BA. For example, the adhesive layer 112 can be made of one of an adhesive polymer, an epoxy resin, a UV curable resin, a polyimide-based resin, an acrylate-based resin, a urethane-based resin, and polydimethylsiloxane (PDMS). However, embodiments of the present disclosure are not limited thereto.

The pixel driving circuit PD can be disposed on the adhesive layer 112 and in the display area AA. When the pixel driving circuit PD is implemented as a driver, the driver can be mounted on the adhesive layer 112 in a transfer process. However, embodiments of the present disclosure are not limited thereto.

A first protective layer 113a and a second protective layer 113b can be disposed on the adhesive layer 112 and the pixel driving circuit PD. The first protective layer 113a and the second protective layer 113b can be disposed to surround a side surface of the pixel driving circuit PD. However, embodiments of the present disclosure are not limited thereto. For example, the second protective layer 113b can be disposed to cover at least a portion of an upper surface of the pixel driving circuit PD. For example, at least one of the first protective layer 113a and the second protective layer 113b disposed on the bending area BA can be omitted. For example, the first protective layer 113a can be entirely disposed in the display area AA and the non-display area NA, and the second protective layer 113b can be partially disposed in the display area AA, the first non-display area NA1, and the second non-display area NA2. For example, a portion of the second protective layer 113b in the bending area BA can be removed. However, embodiments of the present disclosure are not limited thereto.

Each of the first protective layer 113a and the second protective layer 113b can be made of an organic insulating material. However, embodiments of the present disclosure are not limited thereto. For example, each of the first protective layer 113a and the second protective layer 113b can be made of a photoresist, polyimide (PI), or a photo acryl-based material. However, embodiments of the present disclosure are not limited thereto. For example, each of the first protective layer 113a and the second protective layer 113b can be embodied as an overcoat layer or an insulating layer. However, embodiments of the present disclosure are not limited thereto.

According to the present disclosure, a plurality of first connection lines 121 can be disposed on the second protective layer 113b and in the display area AA. The plurality of first connection lines 121 can be lines for electrically connecting the pixel driving circuit PD to other components. For example, the pixel driving circuit PD can be electrically connected to the plurality of signal lines TL and the plurality of contact electrodes CCE via the plurality of first connection lines 121. For example, the plurality of first connection lines 121 can include a (1-1)-th connection line 121a, a (1-2)-th connection line 121b, a (1-3)-th connection line 121c, and a (1-4)-th connection line 121d. However, embodiments of the present disclosure are not limited thereto.

For example, a plurality of (1-1)-th connection lines 121a can be disposed on the second protective layer 113b. The plurality of (1-1)-th connection lines 121a can be electrically connected to the pixel driving circuit PD. The plurality of (1-1)-th connection lines 121a can transmit a voltage output from the pixel driving circuit PD to the first electrode CE1 or the second electrode CE2.

For example, a third protective layer 114 can be disposed on the second protective layer 113b. The protective layer 114 can be entirely disposed in the display area AA and the non-display area NA. In the bending area BA, the third protective layer 114 can cover a side surface of the second protective layer 113b and an upper surface of the first protective layer 113a. The third protective layer 114 can be made of an organic insulating material. For example, the third protective layer 114 can be made of a photoresist, polyimide (PI), or a photo acryl-based material. However, embodiments of the present disclosure are not limited thereto. For example, the first protective layer 113a, the second protective layer 113b, and the third protective layer 114 can be made of the same material. Embodiments of the present disclosure are not limited thereto.

A plurality of (1-2)-th connection lines 121b can be disposed on the third protective layer 114. The plurality of (1-2)-th connection lines 121b can be indirectly connected to the pixel driving circuit PD or can be directly connected thereto. For example, some of the (1-2)-th connection lines 121b can be directly connected to the pixel driving circuit PD via a contact hole of the third protective layer 114. The others of the (1-2)-th connection line 121b can be electrically connected to the (1-1)-th connection line 121a via a contact hole of the third protective layer 114. However, embodiments of the present disclosure are not limited thereto. The voltage output from the pixel driving circuit PD can be transmitted to the first electrode CE1 or the second electrode CE2 via a connection line different from the plurality of (1-2)-th connection lines 121b.

A first insulating layer 115a can be disposed on the plurality of (1-2)-th connection lines 121b. The first insulating layer 115a can be entirely disposed in the display area AA and the non-display area NA. However, embodiments of the present disclosure are not limited thereto. The first insulating layer 115a can be made of an organic insulating material. However, embodiments of the present disclosure are not limited thereto. For example, the first insulating layer 115a can be made of a photo resist, polyimide (PI), or a photo acryl-based material. However, embodiments of the present disclosure are not limited thereto.

A plurality of (1-3)-th connection lines 121c can be disposed on the first insulating layer 115a. The plurality of (1-3)-th connection lines 121c can be electrically connected to the plurality of (1-2)-th connection lines 121b, respectively. For example, the (1-3)-th connection line 121c can be electrically connected to the (1-2)-th connection line 121b via a contact hole of the first insulating layer 115a.

A second insulating layer 115b can be disposed on the plurality of (1-3)-th connection lines 121c. The second insulating layer 115b can be disposed in the remaining area except for the bending area BA. However, embodiments of the present disclosure are not limited thereto. The second insulating layer 115b can be disposed in the display area AA, the first non-display area NA1, and the second non-display area NA2. However, embodiments of the present disclosure are not limited thereto. For example, a portion of the second insulating layer 115b disposed in the bending area BA can be removed. The second insulating layer 115b can be made of an organic insulating material. However, embodiments of the present disclosure are not limited thereto. For example, the second insulating layer 115b can be made of a photo resist, polyimide (PI), or a photo acryl-based material. However, embodiments of the present disclosure are not limited thereto.

A plurality of (1-4)-th connection lines 121d can be disposed on the second insulating layer 115b. The plurality of (1-4)-th connection lines 121d can be electrically connected to the plurality of (1-3)-th connection lines 121c, respectively. For example, the (1-4)-th connection line 121d can be electrically connected to the (1-3)-th connection line 121c via a contact hole of the second insulating layer 115b.

According to the present disclosure, a plurality of second connection lines 122 can be disposed on the second protective layer 113b and in the non-display area NA. The plurality of second connection lines 122 can be lines for transmitting signals transmitted from the flexible circuit board 157 and the printed circuit board 160 (see FIG. 1) to the pad PAD to the pixel driving circuit PD of the display area AA. For example, the plurality of second connection lines 122 can be electrically connected to the plurality of pad electrodes PE respectively to receive signals from the flexible circuit board (or flexible film) 157 and the printed circuit board.

For example, the plurality of second connection lines 122 can extend from the pad PAD toward the display area AA to transmit signals to the lines of the display area AA. In this case, the plurality of second connection lines 122 can function as link lines LL. The plurality of second connection lines 122 can include a (2-1)-th connection line 122a, a (2-2)-th connection line 122b, a (2-3)-th connection line 122c, and a (2-4)-th connection line 122d.

A plurality of (2-1)-th connection lines 122a can be disposed on the second protective layer 113b. The plurality of (2-1)-th connection lines 122a can extend from the second non-display area NA2 to the bending area BA and the first non-display area NA1. The plurality of (2-1)-th connection lines 122a can transmit signals transmitted from the flexible circuit board (or flexible film) 157 and the printed circuit board to the pad PAD to the pixel driving circuit PD of the display area AA. For example, the (2-1)-th connection line 122a can be electrically connected to the pixel driving circuit PD via the first connection line 121 of the display area AA. The (2-1)-th connection line 122a can be electrically connected to the second electrode CE2 via the first connection line 121 and the contact electrode CCE of the display area AA.

A plurality of (2-2)-th connection lines 122b can be disposed on the third protective layer 114. The plurality of (2-2)-th connection lines 122b can be disposed in the second non-display area NA2. The (2-2)-th connection line 122b can be electrically connected to the (2-1)-th connection line 122a via a contact hole of the third protective layer 114. Accordingly, signals from the flexible circuit board (or flexible film) 157 and the printed circuit board can be transmitted to the (2-2)-th connection line 122b via the (2-1)-th connection line 122a.

The (2-3)-th connection line 122c can be disposed on the first insulating layer 115a. The (2-3)-th connection line 122c can be disposed in the second non-display area NA2. The (2-3)-th connection line 122c can be electrically connected to the (2-2)-th connection line 122b via a contact hole of the first insulating layer 115a. Accordingly, signals from the flexible circuit board (or flexible film) 157 and the printed circuit board can be transmitted to the (2-1)-th connection line 122a via the (2-3)-th connection line 122c and the (2-2)-th connection line 122b.

The (2-4)-th connection line 122d can be disposed on the second insulating layer 115b. The (2-4)-th connection line 122d can be disposed in the second non-display area NA2. The (2-4)-th connection line 122d can be electrically connected to the (2-3)-th connection line 122c via a contact hole of the second organic insulating layer 115b. Accordingly, signals from the flexible film FF and the printed circuit board can be transmitted to the (2-1)-th connection line 122a via the (2-4)-th connection line 122d, the (2-3)-th connection line 122c, and the (2-2)-th connection line 122b.

Each of the plurality of first connection lines 121 and the plurality of second connection lines 122 can be made of a conductive material having excellent ductility or various conductive materials used in the display area AA. For example, the second connection line 122, a portion of which is disposed in the bending area BA, can be made of a conductive material having excellent ductility, such as gold (Au), silver (Ag), or aluminum (Al). However, embodiments of the present disclosure are not limited thereto. In another example, each of the plurality of first connection lines 121 and the plurality of second connection lines 122 can be made of molybdenum (Mo), chromium (Cr), titanium (Ti), nickel (Ni), neodymium (Nd), copper (Cu), an alloy of silver (Ag) and magnesium (Mg), or an alloy thereof. However, embodiments of the present disclosure are not limited thereto.

A third insulating layer 115c can be disposed on the plurality of first connection lines 121 and the plurality of second connection lines 122. The third insulating layer 115c can be disposed in the remaining area except for the bending area BA. However, embodiments of the present disclosure are not limited thereto. The third insulating layer 115c can be disposed in the display area AA, the first non-display area NA1, and the second non-display area NA2. A portion of the third insulating layer 115c in the bending area BA can be removed. The third insulating layer 115c can be made of an organic insulating material. However, embodiments of the present disclosure are not limited thereto. For example, the third insulating layer 115c can be made of a photo resist, polyimide (PI), or a photo acryl-based material. However, embodiments of the present disclosure are not limited thereto.

In the display area AA, a plurality of banks BNK can be disposed on the third insulating layer 115c. The plurality of banks BNK can be disposed to overlap the plurality of sub-pixels, respectively. One or more light-emitting elements ED of the same type can be disposed on each of the plurality of banks BNK.

In the display area AA, the plurality of signal lines TL can be disposed on the third insulating layer 115c. The plurality of signal lines TL can be disposed in an area between adjacent ones of the plurality of banks BNK. For example, the plurality of signal lines TL can be disposed adjacent to one of the plurality of banks BNK.

The plurality of contact electrodes CCE can be disposed on the third insulating layer 115c in the display area AA. The plurality of contact electrodes CCE can supply the cathode voltage from the pixel driving circuit PD to the second electrode CE2.

The first electrode CE1 can be disposed on the bank BNK. For example, the first electrode CE1 can be disposed to extend from the adjacent signal line TL toward the top of the bank BNK. The first electrode CE1 can be disposed on an upper surface of the bank BNK and a side surface of the bank BNK. For example, the first electrode CE1 can be disposed to extend from the signal line TL on the upper surface of the third insulating layer 115c to the side surface of the bank BNK and the upper surface of the bank BNK.

Referring to FIG. 9, the first electrode CE1 can be made of a plurality of conductive layers. For example, the first electrode CE1 can include a first conductive layer CE1a, a second conductive layer CE1b, a third conductive layer CE1c, and a fourth conductive layer CE1d. However, embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b, and the fourth conductive layer CE1d can be disposed on the third conductive layer CE1c. For example, each of the first conductive layer CE1a, the second conductive layer CE1b, the third conductive layer CE1c, and the fourth conductive layer CE1d can be made of titanium (Ti), molybdenum (Mo), aluminum (Al), or titanium (Ti) and indium tin oxides (ITO). However, embodiments of the present disclosure are not limited thereto.

According to the present disclosure, some conductive layers having good reflection efficiency among the plurality of conductive layers constituting the first electrode CE1 can act as an alignment key for aligning the light-emitting element ED and/or a reflective plate. For example, the second conductive layer CE1b of the plurality of conductive layers of the first electrode CE1 can include a reflective material. For example, the second conductive layer CE1b can include aluminum (Al). However, embodiments of the present disclosure are not limited thereto. Accordingly, the second conductive layer CE1b can act as the reflective plate. In addition, due to the high reflection efficiency of the second conductive layer CE1b, the second conductive layer CE1b can be easily identified in the manufacturing process, and thus the position of the light-emitting element ED or the transfer position can be aligned with the second conductive layer CE1b.

For example, in order that the second conductive layer CE1b acts as the reflective plate, a portion of each of the third conductive layer CE1c and the fourth conductive layer CE1d covering the second conductive layer CE1b can be removed or etched. For example, an upper surface of the second conductive layer CE1b can be exposed by removing or etching the portion of each of the third conductive layer CE1c and the fourth conductive layer CE1d disposed on the bank BNK. For example, a central portion and an edge portion (or a rim portion) of each of the third conductive layer CE1c and the fourth conductive layer CE1d, on which a solder pattern SDP is disposed, can be left, and the remaining portion other than the central portion and the edge portion thereof can be removed. For example, the edge portion (or the rim portion) of each of the third conductive layer CE1c made of titanium (Ti) and the fourth conductive layer CE1d made of indium tin oxide (ITO) may not be etched. This can prevent the other conductive layers of the first electrode CE1 from being corroded by a tetraMethylammoniumhydroxide (TMAH) solution used in a mask process of the first electrode CE1.

According to the present disclosure, each of the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer such as indium tin oxide (ITO) or indium zinc oxide (IZO), which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process thereon. However, embodiments of the present disclosure are not limited thereto.

According to the present disclosure, each of the signal line TL, the contact electrode CCE, and the pad electrode PE which are disposed at the same layer as a layer of the first electrode CE1, can be composed of multiple layers of a conductive material. However, embodiments of the present disclosure are not limited thereto. For example, each of the signal line TL, the contact electrode CCE, and the pad electrode PE can be composed of a multi-layers structure of indium tin oxide (Indium Tin Oxide, ITO) layer/titanium (Ti) layer/aluminum (Al) layer/titanium (Ti) layer. However, embodiments of the present disclosure are not limited thereto.

According to the present disclosure, the solder pattern SDP can be disposed on the first electrode CE1 and in each of the plurality of sub-pixels. The solder pattern SDP can bond the light-emitting element ED to the first electrode CE1. The first electrode CE1 and the light-emitting element ED can be electrically connected to each other by eutectic bonding by melting of the solder pattern SDP. However, embodiments of the present disclosure are not limited thereto. For example, when the solder pattern SDP is made of indium (In) and the anode electrode 134 of the light-emitting element ED is made of gold (Au), heat and pressure can be applied thereto in the transfer process of the light-emitting element ED to bond the solder pattern SDP and the anode electrode 134 to each other. Via the eutectic bonding, the light-emitting element ED can be bonded to the solder pattern SDP and the first electrode CE1 without a separate adhesive. For example, the solder pattern SDP can be made of indium (In), tin (Sn), or an alloy thereof. However, embodiments of the present disclosure are not limited thereto. For example, the solder pattern SDP can be embodied as a bonding pad, etc. However, embodiments of the present disclosure are not limited thereto.

According to the present disclosure, a passivation layer 116 can be disposed on the plurality of signal lines TL, the plurality of first electrodes CE1, the plurality of contact electrodes CCE, and the third insulating layer 115c. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE in the second non-display area NA2 can be removed. Since the passivation layer 116 is disposed to cover the remaining area except for the bending area BA, an area of the plurality of pad electrodes PE, and an area of the solder pattern SDP, penetration of moisture or impurities flowing into the light-emitting element ED can be reduced. For example, the passivation layer 116 can be formed as a single layer or multiple layers made of silicon oxide (SiOx) or silicon nitride (SiNx). However, embodiments of the present disclosure are not limited thereto. For example, the passivation layer 116 can be embodied as a protective layer, an insulating layer, etc. However, embodiments of the present disclosure are not limited thereto. For example, the passivation layer 116 can have a hole defined therein exposing the solder pattern SDP.

In each of the plurality of sub-pixels, the light-emitting element ED can be disposed on the solder pattern SDP. The first light-emitting element 130 can be disposed in the first sub-pixel SP1. The second light-emitting element 140 can be disposed in the second sub-pixel SP2. The third light-emitting element 150 can be disposed in the third sub-pixel SP3. Each of the plurality of light-emitting elements 130, 140, and 150 can be embodied as a micro light-emitting element.

The light-emitting element ED can be formed on a silicon wafer using a Metal Organic Chemical Vapor Deposition (MOCVD) method, a Chemical Vapor Deposition (CVD) method, a Plasma-Enhanced Chemical Vapor Deposition (PECVD) method, a Molecular Beam Epitaxy (MBE) method, a Hydride Vapor Phase Epitaxy (HVPE) method, or sputtering method. However, embodiments of the present disclosure are not limited thereto.

Referring to FIG. 9, the first light-emitting element 130 can include an anode electrode 134, a first semiconductor layer 131, an active layer 132, a second semiconductor layer 133, a cathode electrode 135, and an encapsulation film 136. However, embodiments of the present disclosure are not limited thereto. For example, the encapsulation film 136 may not be included in the first light-emitting element 130.

The anode electrode 134 can be disposed on the solder pattern SDP. The first semiconductor layer 131 can be disposed on the anode electrode 134. The active layer 132 can be disposed on the first semiconductor layer 131. The second semiconductor layer 133 can be disposed on the active layer 132.

For example, one of the first semiconductor layer 131 and the second semiconductor layer 133 can be made of a compound semiconductor such as a group III-V, a group II-VI, or the like, and can be doped with impurities (or dopants). For example, one of the first semiconductor layer 131 and the second semiconductor layer 133 can be a semiconductor layer doped with n-type impurities, and the other thereof can be a semiconductor layer doped with p-type impurities. However, embodiments of the present disclosure are not limited thereto. For example, at least one of the first semiconductor layer 131 and the second semiconductor layer 133 can be a layer in which n-type or p-type impurities are doped in a material such as gallium nitride (GaN), gallium phosphide (GaP), gallium arsenide phosphide (GaAsP), aluminum gallium indium phosphide (AlGalnP), indium aluminum phosphide (InAIP), aluminum gallium nitride (AlGaN), aluminum indium gallium nitride (AlInN), aluminum gallium arsenide (AlGaAs), or gallium arsenide (GaAs). However, embodiments of the present disclosure are not limited thereto. For example, the n-type impurity can include silicon (Si), germanium (Ge), selenium (Se), carbon (C), tellurium (Te), tin (Sn), etc. However, embodiments of the present disclosure are not limited thereto. For example, the p-type impurity can include magnesium (Mg), zinc (Zn), calcium (Ca), strontium (Sr), barium (Ba), beryllium (Be), etc. However, embodiments of the present disclosure are not limited thereto.

For example, each of the first semiconductor layer 131 and the second semiconductor layer 133 can be made of a nitride semiconductor including n-type impurities and a nitride semiconductor including p-type impurities. However, embodiments of the present disclosure are not limited thereto. For example, the first semiconductor layer 131 can be made of a nitride semiconductor including p-type impurities, and the second semiconductor layer 133 can be made of a nitride semiconductor including n-type impurities. However, embodiments of the present disclosure are not limited thereto.

The active layer 132 can be disposed between the first semiconductor layer 131 and the second semiconductor layer 133. The active layer 132 can receive holes and electrons from the first semiconductor layer 131 and the second semiconductor layer 133 to emit light. For example, the active layer 132 can be composed of one of a single well structure, a multiple well structure, a single quantum well structure, a multi-quantum well (MQW) structure, a quantum dot structure, and a quantum wire structure. However, embodiments of the present disclosure are not limited thereto. For example, the active layer 132 can be made of indium gallium nitride (InGaN) or gallium nitride (GaN). However, embodiments of the present disclosure are not limited thereto.

In another example, the active layer 132 can include a MQW (Multi Quantum Well) structure having a well layer and a barrier layer having a higher band gap than that of the well layer. For example, the active layer 132 can include InGaN as a material of the well layer and AlGaN as a material of the barrier layer. However, embodiments of the present disclosure are not limited thereto.

The anode electrode 134 can be disposed between the first semiconductor layer 131 and the solder pattern SDP. For example, the anode electrode 134 can electrically connect the first semiconductor layer 131 and the first electrode CE1 to each other. The anode voltage output from the pixel driving circuit PD can be applied to the first semiconductor layer 131 via the signal line TL, the first electrode CE1, and the anode electrode 134. For example, the anode electrode 134 can be made of a conductive material capable of eutectic bonding with the solder pattern SDP. However, embodiments of the present disclosure are not limited thereto. For example, the anode electrode 134 can be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, embodiments of the present disclosure are not limited thereto.

The cathode electrode 135 can be disposed on the second semiconductor layer 133. For example, the cathode electrode 135 can electrically connect the second semiconductor layer 133 and the second electrode CE2 to each other. The cathode voltage output from the pixel driving circuit PD can be applied to the second semiconductor layer 133 via the contact electrode CCE, the second electrode CE2, and the cathode electrode 135. The cathode electrode 135 can be made of a transparent conductive material so that light emitted from the light-emitting element ED can be directed upwardly of the light-emitting element ED. However, embodiments of the present disclosure are not limited thereto. For example, the cathode electrode 135 can be made of a material such as Indium Tin Oxide (ITO), Indium Zinc Oxide (IZO), or Indium Gallium Zinc Oxide (IGZO). However, embodiments of the present disclosure are not limited thereto.

The encapsulation film 136 can be disposed on at least a portion of each of the first semiconductor layer 131, the active layer 132, the second semiconductor layer 133, the anode electrode 134, and the cathode electrode 135. For example, the encapsulation film 136 can surround at least a portion of each of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133.

For example, the encapsulation film 136 can be disposed on at least a portion of each of the anode electrode 134 and the cathode electrode 135, for example, an edge portion (or one side surface) of the anode electrode 134 and an edge portion (or one side surface) of the cathode electrode 135. At least a portion of the anode electrode 134 may not be covered with the encapsulation film 136 such that the anode electrode 134 and the solder pattern SDP are connected to each other. For example, at least a portion of the cathode electrode 135 may not be covered with the encapsulation film 136 such that the cathode electrode 135 and the second electrode CE2 are connected to each other. For example, the encapsulation film 136 can be made of an insulating material such as silicon nitride (SiNx) or silicon oxide (SiOx). However, embodiments of the present disclosure are not limited thereto.

In another example, the encapsulation film 136 can have a structure in which a reflective material is dispersed in a resin layer. However, embodiments of the present disclosure are not limited thereto. For example, the encapsulation film 136 can be embodied as a reflector having various structures. However, embodiments of the present disclosure are not limited thereto. Light emitted from the active layer 132 can be reflected upwardly from the encapsulation film 136, thereby improving light extraction efficiency. For example, the encapsulation film 136 can be a reflective layer. However, embodiments of the present disclosure are not limited thereto.

According to the present disclosure, an example in which the light-emitting element ED has a vertical structure has been described. However, embodiments of the present disclosure are not limited thereto. For example, the light-emitting element ED can have a lateral structure or a flip chip structure.

Although the first light-emitting element 130 has been described with reference to FIG. 9, each of the second light-emitting element 140 and the third light-emitting element 150 can have substantially the same structure as that of the first light-emitting element 130. For example, the first semiconductor layer, the active layer, the second semiconductor layer, the anode electrode, the cathode electrode, and the encapsulation film of each of the second light-emitting element 140 and the third light-emitting element 150 can be substantially the same as the first semiconductor layer 131, the active layer 132, the second semiconductor layer 133, the anode electrode 134, the cathode electrode 135, and the encapsulation film 136 of the first light-emitting element 130, respectively.

The optical insulating layer 117 can include a first optical layer 117a, a second optical layer 117b, and a third optical layer 117c.

According to the present disclosure, the first optical layer 117a surrounding the plurality of light-emitting elements ED can be disposed in the display area AA. For example, the first optical layer 117a can be disposed to cover the plurality of light-emitting elements ED and the bank BNK in the areas of the plurality of sub-pixels. For example, the first optical layer 117a can cover the bank BNK, a portion of the passivation layer 116, and an area between adjacent ones of the plurality of light-emitting elements ED. The first optical layer 117a can be disposed in or cover an area between adjacent ones of the plurality of light-emitting elements ED included and an area between adjacent ones of the plurality of banks BNK in one pixel PX. For example, the first optical layer 117a can extend in the first direction X and the first optical layers 117a can be spaced apart from each other in the second direction Y. For example, the first optical layer 117a can be disposed between the passivation layer 116 and the second electrode CE2 so as to surround the side of each of the light-emitting element ED and the bank BNK. However, embodiments of the present disclosure are not limited thereto. For example, the first optical layer 117a can act as a diffusion layer, a sidewall diffusion layer, etc. However, embodiments of the present disclosure are not limited thereto.

The first optical layer 117a can include an organic insulating material in which fine particles are dispersed. However, embodiments of the present disclosure are not limited thereto. For example, the first optical layer 117a can be made of siloxane in which fine metal particles such as titanium dioxide (TiO₂) particles are dispersed. However, embodiments of the present disclosure are not limited thereto. Light from the plurality of light-emitting elements ED can be scattered by the fine particles dispersed in the first optical layer 117a and then emitted out of the display device 1000. Accordingly, the first optical layer 117a can improve extraction efficiency of light emitted from the plurality of light-emitting elements ED.

For example, the first optical layer 117a can be disposed in each of the plurality of pixels PX, or can be commonly disposed in some pixels PX arranged in the same row. However, embodiments of the present disclosure are not limited thereto. For example, the first optical layer 117a can be disposed in each of the plurality of pixels PX, or the plurality of pixels PX can share one first optical layer 117a with each other. In another example, each of the plurality of sub-pixels SP can separately include the first optical layer 117a. However, embodiments of the present disclosure are not limited thereto.

According to the present disclosure, the second optical layer 117b can be disposed on the passivation layer 116 and in the display area AA. For example, the second optical layer 117b can be disposed to surround the first optical layer 117a. For example, the second optical layer 117b can be in contact with a side surface of the first optical layer 117a. For example, the second optical layer 117b can be disposed in an area between adjacent ones of the plurality of pixels PX. However, embodiments of the present disclosure are not limited thereto. For example, the second optical layer 117b can act as a diffusion layer, a diffusion layer window, a window diffusion layer, etc. However, embodiments of the present disclosure are not limited thereto.

The second optical layer 117b can be made of an organic insulating material. However, embodiments of the present disclosure are not limited thereto. The second optical layer 117b can be made of the same material as that of the first optical layer 117a. However, embodiments of the present disclosure are not limited thereto. For example, the first optical layer 117a can include fine particles, and the second optical layer 117b may not include fine particles. For example, the second optical layer 117b can be made of siloxane. However, embodiments of the present disclosure are not limited thereto.

For example, a thickness of the first optical layer 117a can be smaller than a thickness of the second optical layer 117b. However, embodiments of the present disclosure are not limited thereto. Accordingly, in a cross-sectional view of the device, an area in which the first optical layer 117a is disposed can include a concave portion recessed downwardly beyond an upper surface of the second optical layer 117b.

According to the present disclosure, the second electrode CE2 can be disposed on the first optical layer 117a and the second optical layer 117b. For example, the second electrode CE2 can be electrically connected to the plurality of contact electrodes CCE via a contact hole of the second optical layer 117b. For example, the second electrode CE2 can be disposed on the plurality of light-emitting elements ED. For example, the second electrode CE2 can include a transparent conductive oxide such as indium tin oxide (ITO) or indium zinc oxide (IZO). However, embodiments of the present disclosure are not limited thereto. For example, the second electrode CE2 can be disposed to be in contact with the cathode electrode 135. For example, the second electrode CE2 can overlap the first optical layer 117a. For example, the second electrode CE2 can cover a flat upper surface of an outer portion of the first optical layer 117a.

The second electrode CE2 can continuously extend in the first direction of the substrate 110. Accordingly, the plurality of pixels PX arranged in the first direction of the substrate 110 can be commonly connected to the second electrode CE2. For example, the second electrode CE2 can be commonly connected to the plurality of pixels PX.

According to the present disclosure, the second electrode CE2 can continuously extend across the first optical layer 117a, the second optical layer 117b, and the plurality of light-emitting elements ED. An area in which the first optical layer 117a is disposed can include the concave portion recessed downwardly beyond the upper surface of the second optical layer 117b. Accordingly, since a first portion of the second electrode CE2 disposed on the first optical layer 117a is disposed along and on the concave portion, a vertical level of the first portion can be lower than a vertical level of a second portion of the second electrode CE2 disposed on the second optical layer 117b.

The third optical layer 117c can be disposed on the second electrode CE2. The third optical layer 117c can be disposed to overlap the plurality of light-emitting elements ED and the first optical layer 117a. Since the third optical layer 117c is disposed on the second electrode CE2 and the plurality of light-emitting elements ED, a mura that can occur in some of the plurality of light-emitting elements ED can be suppressed. For example, when the plurality of light-emitting elements ED are transferred onto the substrate 110 of the display device 1000, an area in which spacings between adjacent ones of the plurality of light-emitting elements ED are not uniform can occur due to process variations or etc. When the spacings between adjacent ones of the plurality of light-emitting elements ED are non-uniform, respective light emission areas of the plurality of light-emitting elements ED can be non-uniformly arranged, and thus, the mura can be visually recognized by the user. Accordingly, since the third optical layer 117c configured to uniformly diffuse light is formed on top of the plurality of light-emitting elements ED, a phenomenon that the light emitted from some light-emitting elements ED is visible as the mura to the user can be suppressed. Accordingly, the light emitted from the plurality of light-emitting elements ED can be uniformly diffused by the third optical layer 117c and then be extracted out of the display device 1000, such that the luminance uniformity of the display device 1000 can be improved.

The third optical layer 117c can be made of an organic insulating material in which fine particles are dispersed. However, an embodiment of the present disclosure is not limited thereto. For example, the third optical layer 117c can be made of siloxane in which fine metal particles such as titanium dioxide (TiO₂) particles are dispersed. However, embodiments of the present disclosure are not limited thereto. For example, the third optical layer 117c can be made of the same material as that of the first optical layer 117a. However, embodiments of the present disclosure are not limited thereto. For example, the third optical layer 117c can act as a diffusion layer, an upper surface diffusion layer, etc. However, embodiments of the present disclosure are not limited thereto.

According to the present disclosure, light from the plurality of light-emitting elements ED can be scattered by the fine particles dispersed in the third optical layer 117c and be emitted out of the display device 1000. The third optical layer 117c can evenly mix light beams respectively emitted from the plurality of light-emitting elements ED with each other to further improve luminance uniformity of the display device 1000. In addition, light extraction efficiency of the display device 1000 can be improved by the light being scattered from the plurality of fine particles, and accordingly, the display device 1000 can operate at a low power level.

A black matrix BM can be disposed on the second electrode CE2, the first optical layer 117a, the second optical layer 117b, and the third optical layer 117c and in the display area AA. For example, the black matrix BM can fill a contact hole of the second optical layer 117b. Since the black matrix BM is constructed to cover the display area AA, the black matrix can reduce color mixing between light beams from the plurality of sub-pixels and can prevent external light reflection. For example, since the black matrix BM is also disposed in the contact hole via which the second electrode CE2 and the contact electrode CCE are connected to each other, light leakage between adjacent ones of the plurality of sub-pixels can be prevented.

For example, the black matrix BM can be made of an opaque material. However, embodiments of the present disclosure are not limited thereto. For example, the black matrix BM can be made of an organic insulating material to which a black pigment or a black dye is added. However, embodiments of the present disclosure are not limited thereto.

A cover layer 118 can be disposed on the black matrix BM and in the display area AA. The cover layer 118 can protect the components under the cover layer 118. For example, the cover layer 118 can be made of an organic insulating material. However, embodiments of the present disclosure are not limited thereto. For example, the cover layer 118 can be made of a photoresist, polyimide (PI), or a photo acryl-based material. However, embodiments of the present disclosure are not limited thereto. For example, the cover layer 118 can be embodied as an overcoat layer, an insulating layer, etc. However, embodiments of the present disclosure are not limited thereto.

The polarizing layer 293 can be disposed on the cover layer 118 via a first adhesive layer 291. The cover member 155 can be disposed on the polarizing layer 293 via a second adhesive layer 295. For example, each of the first adhesive layer 291 and the second adhesive layer 295 can include an OCA (Optically clear adhesive), an OCR (Optically clear resin), a PSA (Pressure sensitive adhesive), etc. However, embodiments of the present disclosure are not limited thereto.

According to the present disclosure, the plurality of pad electrodes PE can be disposed on the third insulating layer 115c and in the second non-display area NA2. For example, at least a portion of each of the plurality of pad electrodes PE may not be covered with the passivation layer 116 so as to be exposed. For example, the plurality of pad electrodes PE can be electrically connected to the (2-4)-th connection line 122d via a contact hole of the third insulating layer 115c.

An adhesive layer ACF can be disposed on the plurality of pad electrodes PE. The adhesive layer ACF can be an adhesive layer in which conductive balls are dispersed in an insulating material. However, embodiments of the present disclosure are not limited thereto. When heat or pressure is applied to the adhesive layer ACF, the conductive balls can be electrically connected to each other in an area to which the heat or pressure has been applied such that the adhesive layer ACF can be conductive. The adhesive layer ACF can be disposed between the plurality of pad electrodes PE and the flexible circuit board (or flexible film) 157 to attach or bond the flexible circuit board (or flexible film) 157 to the plurality of pad electrodes PE. For example, the adhesive layer ACF can be embodied as an anisotropic conductive film (ACF). However, embodiments of the present disclosure are not limited thereto.

The flexible circuit board (or flexible film) 157 can be disposed on the adhesive layer ACF. The flexible circuit board (or flexible film) 157 can be electrically connected to the plurality of pad electrodes PE by the adhesive layer ACF. Accordingly, the signals output from the flexible circuit board (or flexible film) 157 and the printed circuit board can be transmitted to the pixel driving circuit PD of the display area AA through the plurality of pad electrodes PE, the (2-4)-th connection line 122d, the (2-3)-th connection line 122c, the (2-2)-th connection line 122b, and the (2-1)-th connection line 122a.

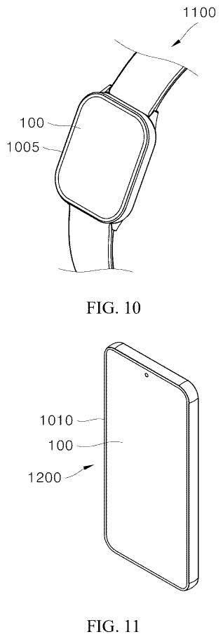

FIGS. 10 to 13 are diagrams illustrating an apparatus to which a display device according to embodiments of the present disclosure is applied.

Referring to FIGS. 10 to 13, a display device 1000 according to embodiments of the present disclosure can be included in various apparatus or electronic devices. For example, referring to FIGS. 10 to 13, various electronic devices can include a wearable device 1100, a mobile device 1200, a notebook computer 1300, and a monitor or TV 1400. However, embodiments of the present disclosure are not limited thereto.

Each of the wearable device 1100, the mobile device 1200, the notebook computer 1300, and the monitor or TV 1400 can include a casing 1005, 1010, 1015, or 1020 and the display device 1000 including the display panel 100 and according to embodiments of the present disclosure as described above with reference to FIGS. 1 to 9.

For example, the display device according to an embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), a MP3 player, a mobile medical device, a desktop PC, a laptop PC, a netbook computer, a workstation, a navigation system, a vehicle display device, a theater display device, a television, a wall paper device, a signage device, a game device, a notebook computer, a monitor, a camera, a camcorder, a home appliance, etc.

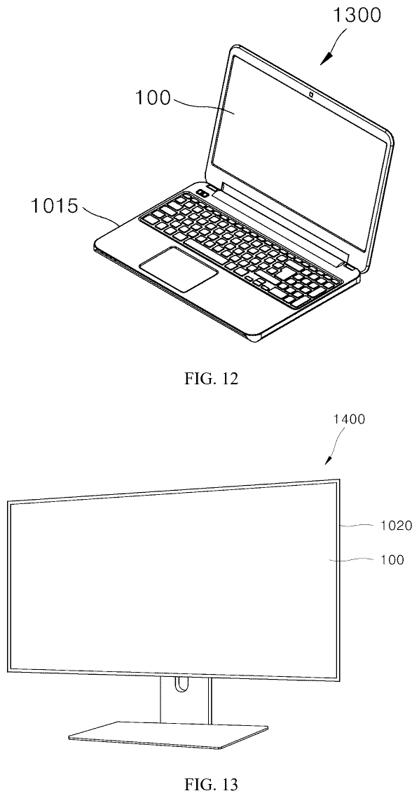

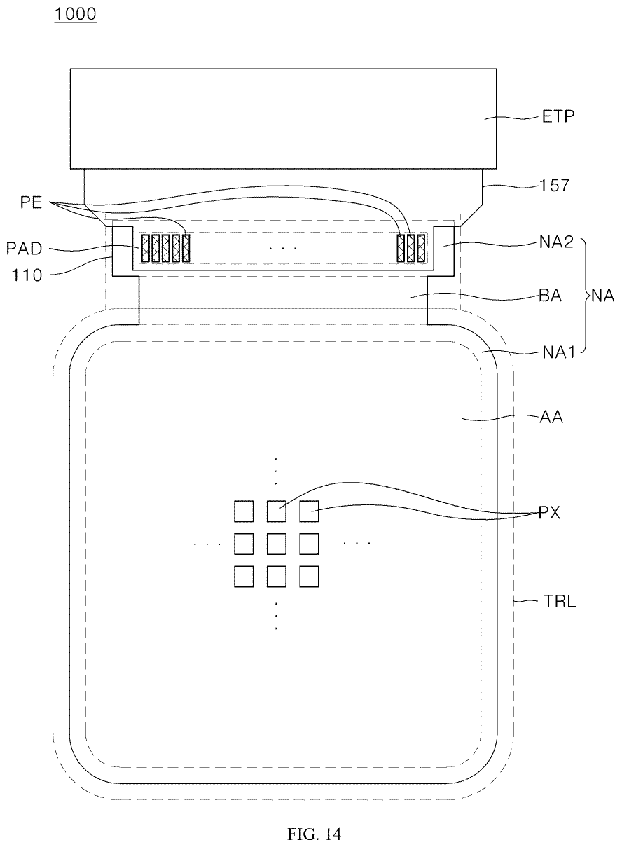

FIG. 14 is a plan view illustrating a test pad and a trimming line of a display device according to an embodiment of the present disclosure, and FIG. 15 is a cross-sectional view illustrating an example of an operation test during a manufacturing process of a light-emitting element according to an embodiment of the present disclosure.

Referring to FIG. 14, in a display device 1000 according to an embodiment of the present disclosure, a substrate 110 including a display area AA and a non-display area NA can be cut along a trimming line TRL.

The non-display area NA can include a first non-display area NA1 surrounding the display area AA, a bending area BA extending from one side of the first non-display area NA1, and a second non-display area NA2 extending outwardly from the bending area BA.

The second non-display area NA2 can include a pad PAD. The pad PAD can include a pad electrode PE electrically connected to the plurality of pixels PX.

The flexible circuit board 157 can extend outwardly from the second non-display area NA2 including the pad PAD. A test pad ETP can be disposed outside the flexible circuit board 157. The printed circuit board 160 extending outwardly from the flexible circuit board 157 can operate as the test pad ETP. In FIG. 14, the test pad ETP and the pad PAD are separately illustrated. However, embodiments of the present disclosure are not limited thereto, and the test pad ETP can be configured to include the pad PAD. The test pad ETP can be electrically connected to each pad electrode PE of the pad PAD.

Referring to FIGS. 14 and 15, the first electrode CE1 can be disposed under each of the plurality of light-emitting elements 130, 140, and 150, and the second electrode CE 2 can be disposed on top of each of the plurality of light-emitting elements 130, 140, and 150. Each of the first electrodes CE1 can be connected to each of the signal lines TL, and each of the signal lines TL can be connected to each of the pad electrodes PE through the second connection line 122. The first electrode CE1 can be, for example, an anode electrode, and the second electrode CE 2 can be, for example, a cathode electrode.

The second connection line 122 can include the (2-1)-th connection line 122a, the (2-2)-th connection line 122b, the (2-3)-th connection line 122c, and the (2-4)-th connection line 122d. The (2-1)-th connection line 122a can be disposed on the first protective layer 113a and the second protective layer 113b. The third protective layer 114 can be disposed on the (2-1)-th connection line 122a. The (2-2)-th connection line 122b can be disposed on the third protective layer 114. The first insulating layer 115a can be disposed on the (2-2)-th connection line 122b. The (2-3)-th connection line 122c can be disposed on the first insulating layer 115a. The second insulating layer 115b can be disposed on the (2-3)-th connection line 122c, and the (2-4)-th connection line 122d can be disposed on the second insulating layer 115b. Adjacent ones of the (2-1)-th connection line 122a, the (2-2)-th connection line 122b, the (2-3)-th connection line 122c, and the (2-4)-th connection line 122d can be electrically connected to each other via a contact hole.

As each of the light-emitting elements 130, 140, and 150 is electrically connected to the pad electrode PE through the signal line TL and the second connection line 122, an operation state of each of the light-emitting elements 130, 140, and 150 can be tested using the pad electrode PE. Accordingly, a E-test 2 (emission) test for inspecting an emission operation of each of the plurality of light-emitting elements 130, 140, and 150 can be performed using the pad electrode PE.

An electric field near each of the light-emitting elements 130, 140, and 150 can be applied to each light-emitting element in a non-contact manner. Each of the light-emitting elements 130, 140, and 150 can receive the electric field in the non-contact manner in a state in which the first electrode CE1 is disposed under the light-emitting elements 130, 140, and 150 and the second electrode CE2 is not disposed on top of each of the light-emitting elements 130, 140, and 150.

Accordingly, each of the light-emitting elements 130, 140, and 150 can generate a current under the electric field. The current can be transmitted to the pad electrode PE through the signal line TL and the second connection line 122.

Accordingly, the operation state of each of the light-emitting elements 130, 140, and 150 can be inspected using a ET2 tester in contact with the pad electrode PE. In this regard, the ET2 tester is a test equipment that applies a current to the pad electrode PE or detects a current from the pad electrode PE.

In addition, the ET2 tester can apply a test current to the pad electrode PE. Accordingly, the test current can be applied from the pad electrode PE to the light-emitting element 130 through the second connection line 122 and the signal line TL. Accordingly, the light-emitting element 130 can perform a light-emitting operation based on the applied test current.

In this case, each of the light-emitting elements 130, 140, and 150 can perform a light-emitting operation in a normal case, and may not emit light in an abnormal case.

Each of the light-emitting elements 130, 140, and 150 can be disposed in a layer different from a layer of the driving chip PD in the display area AA and can be electrically connected to the driving chip PD.

In this regard, a E-test 1 (signal) test can be performed to check whether a signal is normally transmitted and received to and from the driving chip PD and each of the plurality of light-emitting elements 130, 140, and 150.

As described above, according to an embodiment of the present disclosure, a E-test 2 test can be performed on each of the plurality of light-emitting elements 130, 140, and 150. Each of the light-emitting elements 130, 140, and 150 can include a main (primary) light-emitting element and a redundant light-emitting element. The E-test 2 test can be classified into light-emitting device (LED) binning, display binning, and display grading. In the light-emitting element binning, each of high, low, and typical currents can be applied to each of the light-emitting elements 130, 140, and 150 through the pad electrode PE and the luminance of light emitted therefrom can be measured and then an LED grade can be designated based on the measured luminance. In the display binning, a grade on the LED binning can be designated based on the number of LED DPPMs (functional part per million). In the display grading, a grade of each cell can be designated based on a combination of results of the E-test 1 and E-test 2 tests. In this regard, in one example, the cell as one light-emitting unit can be composed of the first light-emitting element 130, the second light-emitting element 140, and the third light-emitting element 150.

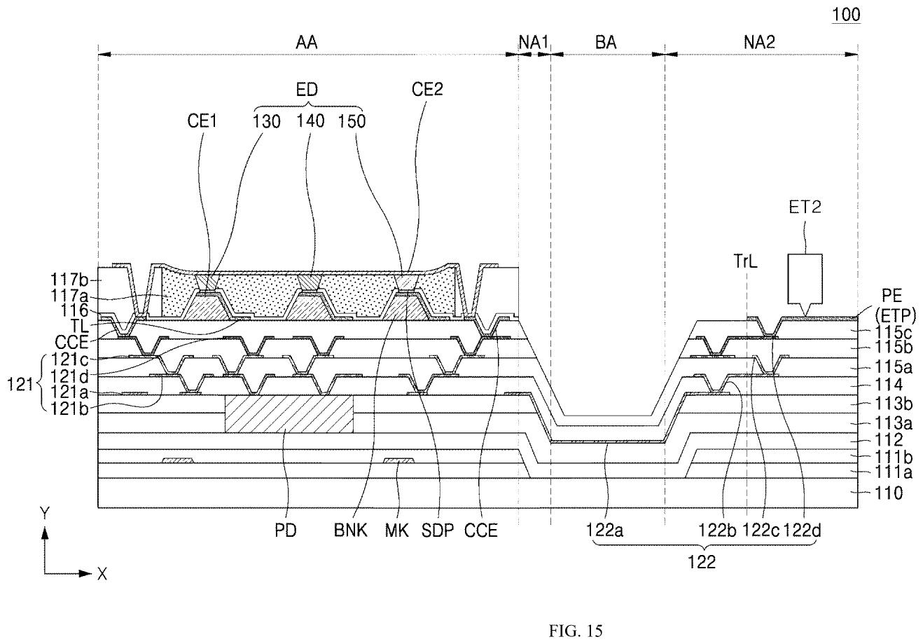

FIG. 16 is a diagram illustrating an example of BM masking of a light-emitting element in a display device according to an embodiment of the present disclosure.

Referring to FIG. 16, the display device according to an embodiment of the present disclosure can be subjected to the BM masking after testing each of the light-emitting elements 130, 140, and 150 as shown in FIG. 15.

In the display device according to an embodiment of the present disclosure, openings OP1 to OP3 can be defined at positions corresponding to the plurality of light-emitting elements 130, 140, and 150, respectively.

The plurality of light-emitting elements can include the first light-emitting element 130 emitting red light, the second light-emitting element 140 emitting green light, and a third light-emitting element 150 emitting blue light.

In the transfer process according to an embodiment of the present disclosure, the respective main light-emitting elements 130a, 140a, and 150a of the light-emitting elements 130, 140, and 150 can be first transferred to the panel substrate.

In each of the main light-emitting elements 130a, 140a, and 150a, as shown in FIG. 15, the E-test 2 test can be performed to determine that the first main light-emitting element 130a and the second main light-emitting element 140a are normal (OK) and the third main light-emitting element 150a is defective (see (a) of FIG. 16).

Accordingly, the redundant light-emitting element 150b of the third light-emitting element 150 can be transferred to the panel substrate in an additional transfer process (see (b) of FIG. 16).

In this case, the redundant light-emitting element 150b of the third light-emitting element 150 can be tested using the E-test2 as shown in FIG. 15, and thus the redundant light-emitting element 150b can be determined to be normal (OK).

Thereafter, a black matrix BM can be formed so as not cover the first main light-emitting element 130a, the second main light-emitting element 140a, and the third redundant light-emitting element 150b so as to be exposed in the BM masking process (see (c) of FIG. 16).

The black matrix BM can be disposed on the plurality of light-emitting elements 130a, 140a, and 150b such that the plurality of light-emitting elements 130a, 140a, and 150b are respectively exposed through the openings OP1 to OP3.

Each opening OP can be formed to correspond to the main light-emitting element or the redundant light-emitting element of each of the plurality of light-emitting elements.

The first light-emitting element can be a main light-emitting element or a redundant light-emitting element, the second light-emitting element can be a main light-emitting element or a redundant light-emitting element, and the third light-emitting element can be a main light-emitting element or a redundant light-emitting element.

In the display device according to an embodiment of the present disclosure, the first opening OP1 can be formed to correspond to the first main light-emitting element 130a, the second opening OP2 can be formed to correspond to the second main light-emitting element 140a, and the third opening OP3 can be formed to correspond to the third redundant light-emitting element 150b.

In the display device according to an embodiment of the present disclosure, the main light-emitting elements 130a, 140a, and 150a of the plurality of light-emitting elements are first transferred, and the electric field is applied to each of the main light-emitting elements 130a, 140a, and 150a, respectively, to perform a lighting test. In this regard, the redundant light-emitting element 150b corresponding to the main light-emitting element (e.g., 150a) from which no current is detected through the pad electrode PE is transferred on the panel substrate. The black matrix BM fills the opening OP corresponding to the defective main light-emitting element 150a from which no current is detected through the pad electrode PE and covers the defective main light-emitting element 150a. Conventionally, six light-emitting elements including the three main light-emitting element and the three redundant light-emitting elements per pixel can be transferred on the panel substrate. However, according to the present disclosure, four light-emitting elements including the three main light-emitting element and only one redundant light-emitting element corresponding to the defective main light-emitting element per pixel can be transferred on the panel substrate, such that the material can be saved.

In the display device, the electric field can be applied to each of the plurality of light-emitting elements in a non-contact manner, and the opening corresponding to the light-emitting element 150a in which a current is not detected through the pad electrode PE can be covered with the black matrix BM.

The electric field can be applied to the main light-emitting element and the redundant light-emitting element of each of the plurality of light-emitting elements, respectively. Then, based on the lighting test result, the opening corresponding to the main light-emitting element or the redundant light-emitting element from which no current is detected through the pad electrode PE can be filled with the black matrix, and further, the main light-emitting element or the redundant light-emitting element from which no current is detected through the pad electrode PE can be covered with the black matrix.

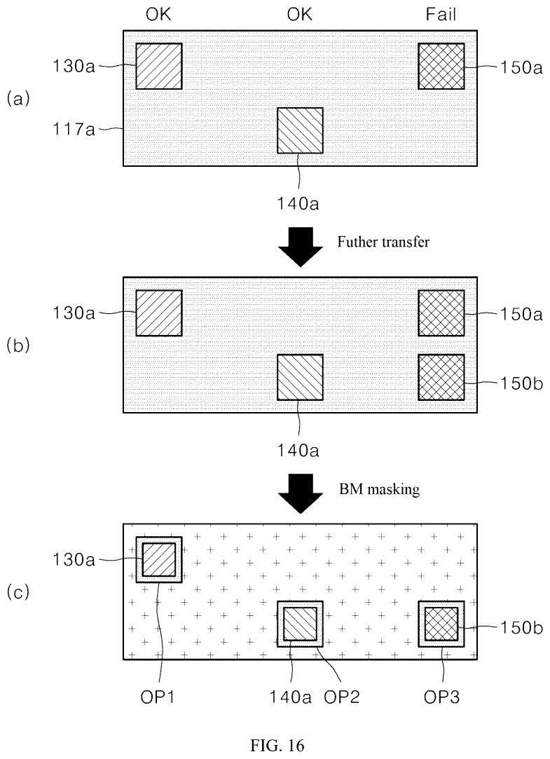

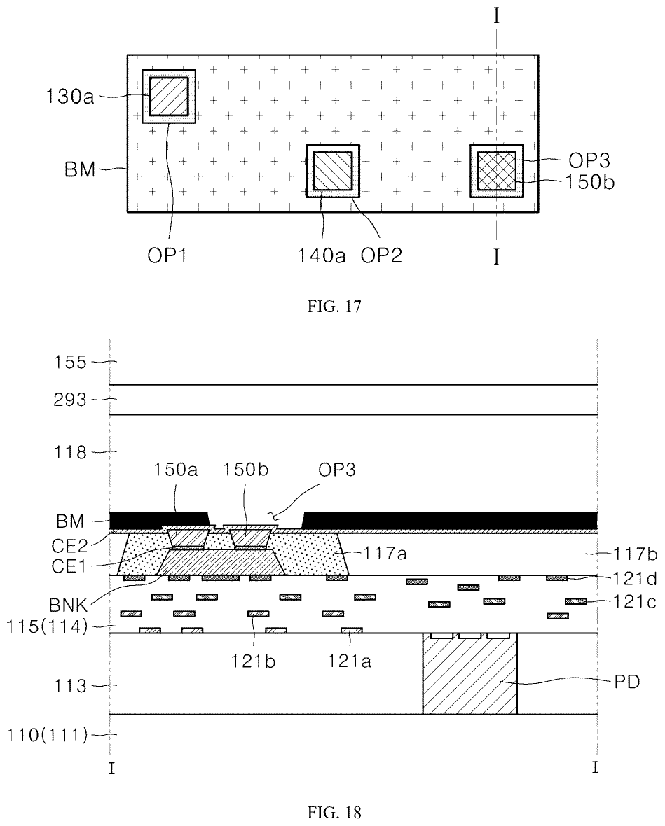

FIG. 17 is a plan view illustrating an example of a light-emitting element arrangement after the BM masking according to an embodiment of the present disclosure, and FIG. 18 is a cross-sectional view illustrating a cross-section of the light-emitting element of FIG. 17 taken along a cutting line I-I.

Referring to FIG. 17, the first opening OP1, the second opening OP2, and the third opening OP3 can be formed in the black matrix BM of the display device according to an embodiment of the present disclosure.

The first opening OP1 can correspond to a main light-emitting element or a redundant light-emitting element of the first light-emitting element 130, the second opening OP2 can correspond to a main light-emitting element or a redundant light-emitting element of the second light-emitting element 140, and the third opening OP3 can correspond to a main light-emitting element or a redundant light-emitting element of the third light-emitting element 150.

Accordingly, in the display device, the first main light-emitting element 130a can be exposed through the first opening OP1, the second main light-emitting element 140b can be exposed through the second opening OP2, and the third redundant light-emitting element 150b can be exposed through the third opening OP3.

Referring to FIG. 18, regarding the third light-emitting element 150, the main light-emitting element 150a can be covered with the black matrix BM, and the redundant light-emitting element 150b can be exposed through the third opening OP3. For example, it can be identified that the main light-emitting element 150a is covered with the black matrix BM because the main light-emitting element 150a is determined to be defective based on the test result as shown in FIG. 15.

At least two of the first to third openings can have the same size. The first opening OP1 and the second opening OP2 can have the same area and size. The second opening OP2 and the third opening OP3 can have the same area and size. The first opening OP1 and the third opening OP3 can have the same area and size.

Referring to FIGS. 8, 15, and 18, the first light-emitting element 130, the second light-emitting element 140, and the third light-emitting element 150 can constitute one light-emitting unit and be arranged horizontally. In this case, the black matrix BM can be disposed to fill a contact hole disposed outwardly of the first light-emitting element 130 and a contact hole disposed outwardly of the third light-emitting element 150. Further, the black matrix BM can be disposed on the plurality of light-emitting elements and in an area between the first light-emitting element 130 and the second light-emitting element 140 and an area between the second light-emitting element 140 and the third light-emitting element 150.

The black matrix BM can be made of an opaque material. The black matrix BM can include an organic insulating material to which a black pigment or a black dye is added. Each of the plurality of light-emitting elements can include a micro light-emitting element.

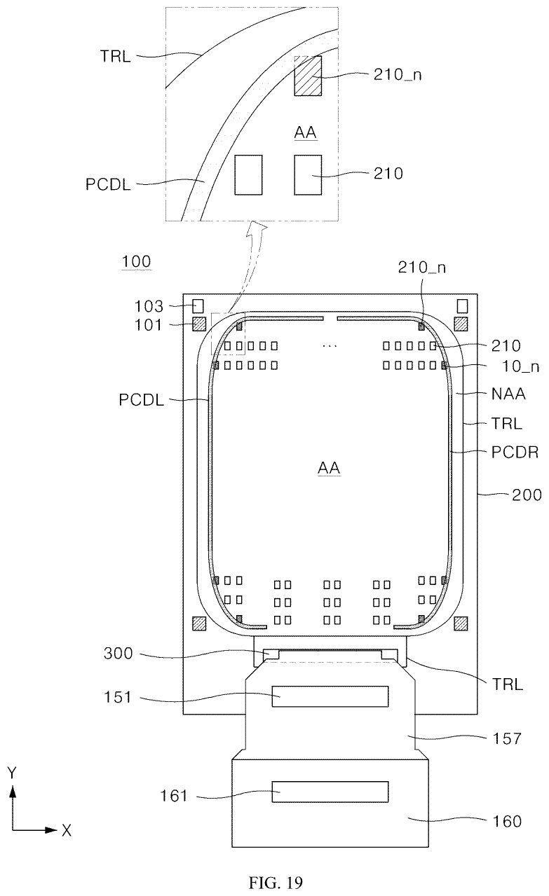

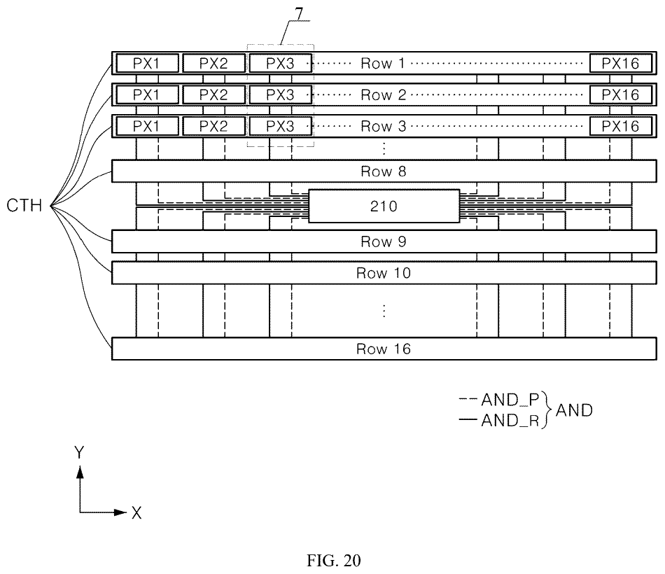

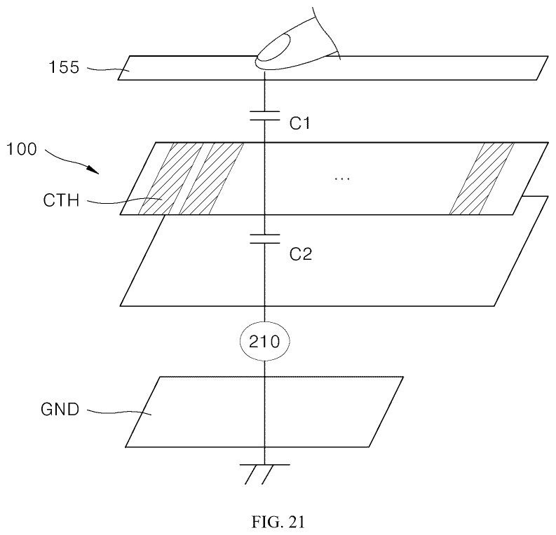

FIG. 19 is a plan view of a display device according to another embodiment of the present disclosure. FIG. 20 is a plan view illustrating an area in which one pixel driving circuit among a plurality of pixel driving circuits of FIG. 19 is disposed. FIG. 21 is a view illustrating a touch operation of a display device according to another embodiment of the present disclosure.

Referring to FIGS. 19 and 20, in a display area AA of a substrate 200 according to another embodiment of the present disclosure, a plurality of pixels PX1, PX2, PX3, . . . , PX16 including a plurality of driving chips 210 as the pixel driving circuits PD and a plurality of light-emitting elements electrically connected to the driving chips 210 can be arranged. Each driving chip 210 can supply a control signal and power to the plurality of light-emitting elements to control a light-emitting operation of the plurality of light-emitting elements.

The substrate 200 can have a shape in which a length of one side is larger than a length of the other side. For example, the substrate 200 can include a long side having a larger length and a short side having a smaller length than that of the long side. The short side can extend in the first direction X of the substrate 200, and the long side can extend in the second direction Y of the substrate 200. However, embodiments of the present disclosure are not limited thereto.

One or more crack detection lines PCDL and PCDR can be disposed in a partial area of the non-display area NA. Each of the one or more crack detection lines PCDL and PCDR can extend along an outer edge of the display area AA and can detect a defect such as a crack that can occur in the outer edge of the display area AA. The one or more crack detection lines PCDL and PCDR can extend along at least both opposing sides and a portion of each of upper and lower sides of the display area AA. For example, the one or more crack detection lines PCDL and PCDR can include a first crack detection line PCDL and a second crack detection line PCDR.

The first crack detection line PCDL can extend along a left long side of the substrate 200 and can extend to each of upper and lower left corners and then can extend along a left portion of each of upper and lower short sides. The second crack detection line PCDR can extend along a right long side of the substrate 200 and can extend to each of upper and lower right corners and then can extend along a right portion of each of the upper and lower short sides. The first crack detection line PCDL and the second crack detection line PCDR. can be spaced apart from each other.

Each of the first crack detection line PCDL and the second crack detection line PCDR. can be disposed to overlap some of the plurality of driving chips 210 at each corner area. The driving chip DC disposed to overlap the first and second crack detection lines PCDL and PCDR in the corner area can be an inactive driving chip 210_n.

The inactive driving chip 210_n can be disposed to overlap the first crack detection line PCDL or the second crack detection line PCDR at the corner area of the substrate 200, and thus may not be electrically connected to at least a portion of the power line or the signal line. Accordingly, the inactive driving chip 210_n can be an unused driving chip that does not control the plurality of light-emitting elements. The inactive driving chip 210_n can include at least eight driving chips arranged along the four corner areas of the substrate 200 among the plurality of driving chips 210. For example, two inactive driving chips 210_n can be disposed in each of the four corner areas of the substrate 200.

The substrate 200 can include a trimming line TRL extending along an outer edge of the non-display area NA. The trimming line TRL can be a cutting line cut by a laser beam during a scribing process for dividing the substrate 200 into a plurality of display panels 100 (see FIG. 1) as individual units. An area disposed outwardly of the trimming line TRL can be removed in the scribing process.

A plurality of alignment key patterns 101 and 103 can be disposed in the area disposed outwardly of the trimming line TRL. The plurality of alignment key patterns 101 and 103 can include a first alignment key pattern 101 and a second alignment key pattern 103. However, embodiments of the present disclosure are not limited thereto. Since the plurality of alignment key patterns 101 and 103 are disposed in the area disposed outwardly of the trimming line TRL, they can be removed in the scribing process.

The first alignment key pattern 101 can be a pattern for alignment between the display panel 100 and the cover member 155 of FIG. 1. At least one of the plurality of first alignment key patterns 101 can be positioned in the area disposed outwardly of the trimming line TRL facing each corner area of the substrate 200. For example, each first alignment key patterns 101 can be disposed at each of four corner areas of the substrate 200. Thus, the plurality of first alignment key patterns 101 can include four alignment key patterns.

The second alignment key pattern 103 can include various alignment key patterns for aligning components respectively disposed in different layers, such as a plurality of signal lines, contact holes, and a plurality of driving chips disposed on the substrate 200 at correct positions. The second alignment key pattern 103 can include a metal material. Accordingly, the second alignment key pattern 103 can be disposed on the display area AA or the non-display area NA and can be formed at the same time as a time at which a plurality of signal lines including a metal material is formed. However, embodiments of the present disclosure are not limited thereto.

The plurality of driving chips 210 as the pixel driving circuits can be disposed on the display area AA of the substrate 200. For example, the plurality of driving chips 210 can be arranged in a matrix shape. However, embodiments of the present disclosure are not limited thereto.

A plurality of pixels including a plurality of light-emitting elements can be arranged in a matrix shape while being respectively disposed on the plurality of driving chips 210.

The plurality of pixels can be arranged to be spaced apart from each other in each of the first direction DR1 and the second direction DR2 intersecting the first direction DR1. The first direction can be an X-axis direction of the display panel 100, and the second direction can be a Y-axis direction of the substrate 200. However, embodiments are not limited thereto. For example, the first direction can be a transverse direction or a row direction of the substrate 200, and the second direction can be a longitudinal direction or a column direction of the substrate 200.

In each of the plurality of pixels, sub-pixels respectively emitting different colors can be alternately arranged with each other in the first direction DR1 of the substrate 200. In addition, sub-pixels emitting the same color can be arranged in the second direction DR2 of the substrate 200. For example, the first to 16th pixels PX1 to PX16 can be arranged in the row direction as the first direction. One pixel PX can include red (R), green (G), and blue (B) sub-pixels.

A plurality of light-emitting element can be disposed in each of the sub-pixels. At least one light-emitting element can be disposed in one sub-pixel. For example, two light-emitting elements can be disposed in one sub-pixel. One of the two light-emitting elements can act as a main light-emitting element, and the other thereof can act as a redundant light-emitting element. The light-emitting element can be embodied as a micro LED (μLED). Accordingly, the red (R), green (G), and blue (B) sub-pixels can be repeatedly arranged in this order in the first direction, for example, the row direction.

In addition, the sub-pixels emitting light of the same color can be arranged in the column direction as the second direction. For example, the sub-pixels emitting light of one color among red (R), green (G), and blue (B) colors can be arranged in the column direction as the second direction. The sub-pixels emitting light of the same color can be electrically connected to each other via lines of first electrode AND_P and AND_R.

The first electrode AND can include a first line AND_P and a second line AND_R. The first line AND_P and the second line AND_R can be spaced apart from each other in the first direction DR1 of the substrate 200. The first line AND_P of the first electrode AND can be connected to the main light-emitting element, and the second line AND_R of the first electrode AND can be connected to the redundant light-emitting element.

Each of a plurality of second electrodes CTH can extend in the first direction. In addition, the plurality of second electrodes CTH can be arranged to be spaced apart from each other in the second direction. Accordingly, each of the second electrodes CTH can extend in the first direction and can be connected to the first pixel PX1 to the 16th pixel PX16 arranged in each of a plurality of rows Row 1, Row2, Row 3, . . . , Row 16.

Each of the plurality of driving chips 210 can include a plurality of driving circuits to drive the plurality of light-emitting elements. One driving chip 210 can be connected to the plurality of first electrodes AND and the plurality of second electrodes CTH respectively connected to the plurality of pixels PX1, PX2, PX3, . . . , PX16. For example, one driving chip 210 can drive the plurality of light-emitting elements arranged in the first row Row 1 to the 16th row Row 16. In other words, one driving chip 210 can be electrically connected to the plurality of light-emitting elements arranged in the first row Row 1 to the 16th row Row 16 via the first electrodes AND and the second electrodes CTH, and can supply a control signal and power thereto via the first electrodes AND and the second electrodes CTH to control the light-emitting operations of the plurality of light-emitting elements.

The plurality of first electrodes AND connected to at least one driving chip 210 can be radially connected to connect each of the first sub-pixel SP1 disposed at a first position of the first row Row 1 to the 16th sub-pixel SP16 opposite to the first sub-pixel SP1 and disposed at a 16th position thereof to the driving chip 210. For example, a shape in which the plurality of first electrodes AND are connected to the driving chip 210 can be a rhombus shape or a ‘I’ shape in a plan view of the device.

The display device according to an embodiment of the present disclosure can have an in-cell touch structure in which each of the plurality of second electrodes CTH is used as a touch electrode instead of forming a separate touch electrode. Accordingly, since the separate touch electrode is not formed, a thickness of the display panel can be reduced.

Referring to FIG. 21, when a user's touch operation is performed on the cover member 155, a change in a first capacitance C1 between each of the plurality of second electrodes CTH disposed on the substrate of the display panel 100 and the cover member 155 and a change in a second capacitance C2 between each of the plurality of second electrodes CTH and each of a plurality of signal lines M_SL can be detected and provided to the driving chip 210. In addition, the driving chip 210 can perform a touch control function to provide a control signal based on the touch input to the plurality of light-emitting elements. A ground GND can be disposed to be opposite to the cover member 155 while the plurality of second electrodes CTH are disposed between the cover member and the ground.

A touch sensing scheme of a capacitance substrate can include a self-capacitance operation scheme and a mutual capacitance operation scheme for sensing a touch based on a detecting result of a change in a capacitance between two types of touch sensors.

The display device 1000 according to an embodiment of the present disclosure can perform the touch operation and the touch sensing in the self-capacitance-based touch sensing scheme, or can perform the touch operation and the touch sensing in the mutual-capacitance-based touch sensing scheme.

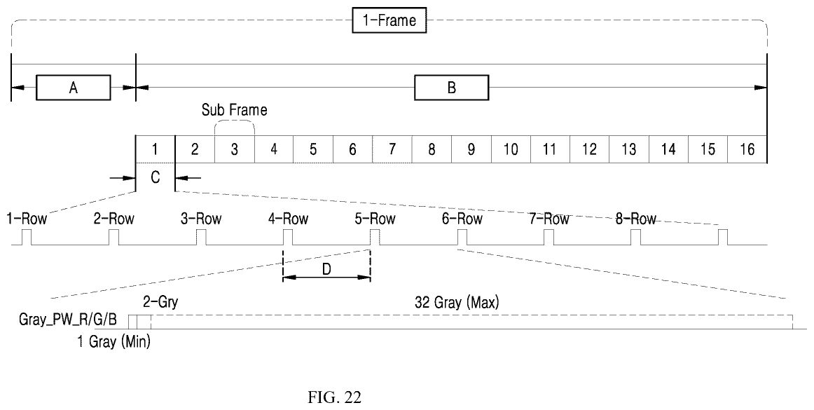

FIG. 22 illustrates an example of a signal waveform diagram when a display device according to an embodiment of the present disclosure operates.

Referring to FIG. 22, the display device according to an embodiment of the present disclosure can perform a light emission operation on one frame basis.

One frame can include a touch period A and a display period B.

One frame can operate at a frequency of, for example, 60 Hz. In this case, the touch period A can operate for a first time duration at a frequency of, for example, 60 Hz, and the display period B can operate for a second time duration larger than the first time duration at a frequency of, for example, 60 Hz. Accordingly, the operation time duration of the touch period A and the operation time duration of the display period B in one frame can be different from each other. For example, the operation time duration of the touch period A can be shorter than the operation time duration of the display period B.

The display period B can include 16 sub-frames.

For example, when, in the display panel DP, eight light-emitting elements are connected to one anode electrode line as the first electrode, one sub-frame period C can include eight pulse signals 1-Row, 2-Row, 3-Row, 4-Row, 5-Row, 6-Row, 7-Row, and 8-Row. For example, in an embodiment of the present disclosure, eight micro light-emitting elements (μLED) can operate during one sub frame.

Accordingly, in an embodiment of the present disclosure, one frame includes 16 sub-frames and one sub-frame includes 8 pulse signals, such that 128 micro light-emitting elements (μLED) can operate for one frame.

An embodiment of the present disclosure is not limited thereto. For example, when 16 micro light-emitting elements (μLED) are connected to one anode electrode line as the first electrode, one sub-frame period C can include 16 pulse signals. In this case, 256 micro light-emitting elements (μLED) can operate for one frame.

One pulse signal (e.g., 5-Row) drives one micro light-emitting element (μLED). One pulse signal period D can include a high signal period and a low signal period. In this regard, a time duration of the low signal period can be larger than a time duration of the high signal period.

In an embodiment of the present disclosure, an operation time duration of the micro light-emitting element (μLED) can be controlled based on a light-emission signal EM applied to the gate electrode of the light-emission transistor T_{EM}.

A micro driver (μDriver) can control an application time duration of the light-emission signal EM based on a pulse width PW. For example, a case in which one pulse signal (e.g., 5-Row) is applied to the gate electrode of the light-emission transistor T_{EM} using one pulse width PW can be referred to as one gray.

In order to control the application time duration of the light-emission signal EM, the micro driver (μDriver) can apply one pulse signal (e.g., 5-Row) using the pulse width PW varying from a minimum of 1 Gray (Min) to a maximum of 32 Gray (Max).

One pixel PX can include red (R), green (G), and blue (B) sub-pixels. Each of the plurality of micro light-emitting elements (μLED) can be disposed in the sub-pixel.

Accordingly, the micro driver (μDriver) can control a light-emission time duration of the micro light-emitting element (μLED) corresponding to each of red (R), green (G), and blue (B) sub-pixels by applying the pulse signal of which the pulse width PW is adjusted from a minimum of 1 Gray (Min) to a maximum of 32 Gray (Max) to the gate electrode of the light-emission transistor T_{EM}.

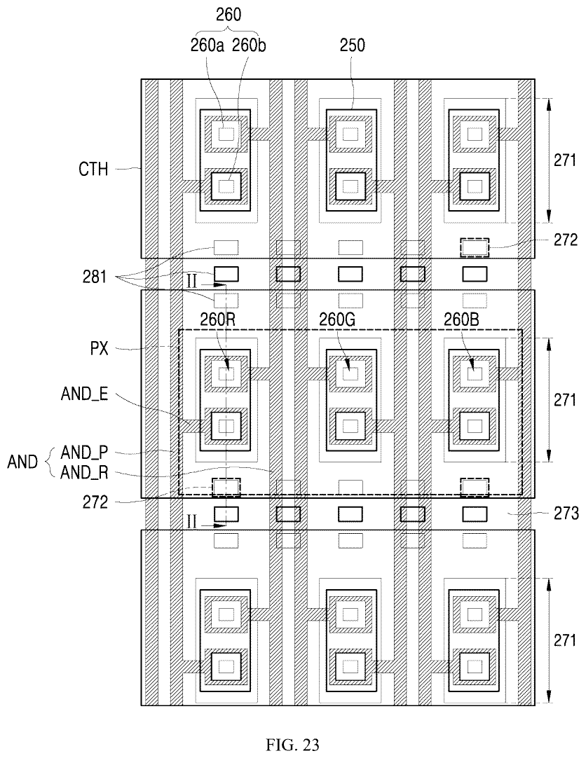

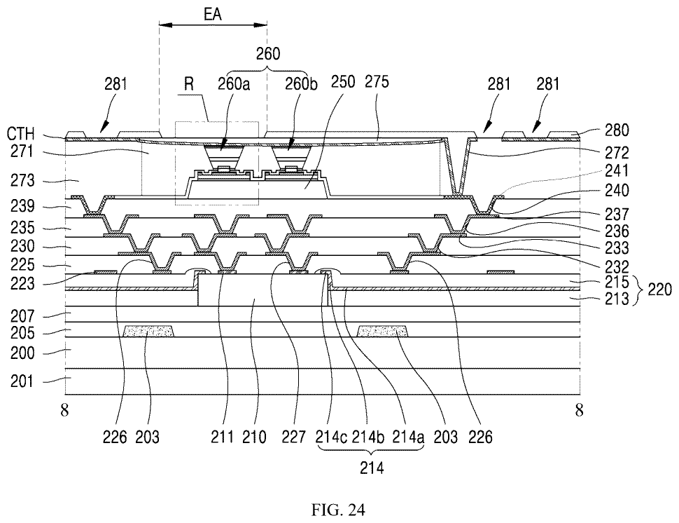

FIG. 23 is an enlarged plan view illustrating an area 7 of FIG. 20 according to another embodiment of the present disclosure. FIG. 24 is a cross-sectional view taken along a line II-II of FIG. 23. For convenience of illustration, FIG. 23 illustrates the first electrode AND, the second electrode CTH, a plurality of light-emitting elements 260, a bank 250, optical insulating layers 271 and 273.

Referring to FIGS. 23 and 24, the display device according to another embodiment of the present disclosure can include a plurality of first electrodes AND arranged and disposed on the substrate 200, the solder pattern SDP disposed on a plurality of first electrodes AND, the plurality of light-emitting elements 260 electrically connected to the plurality of first electrodes AND, the optical insulating layers 271, 273 and 275, a plurality of second electrodes CTH disposed on the plurality of light-emitting elements 260, and a contact electrode 272.

The plurality of first electrodes AND can be arranged to be spaced apart from each other in the first direction of the substrate 200. The plurality of first electrodes AND can extend in the second direction intersecting the first direction. The first direction can be an X-axis direction of the substrate 200, and the second direction can be a Y-axis direction of the substrate 200. However, embodiments are not limited thereto. For example, the first direction can be a transverse direction or a row direction of the substrate 200, and the second direction can be a longitudinal direction or a column direction of the substrate 200.

The plurality of first electrodes AND can include a first line AND_P and a second line AND_R. The first line AND_P and the second line AND_R can be spaced apart from each other in the first direction DR1 of the substrate 200. Each of the first line AND_P and the second line AND_R can include an extension portion AND_E electrically connected to the light-emitting element 260.

Each of the first line AND_P and the second line AND_R of the plurality of first electrodes AND can be connected to the solder pattern SDP. The plurality of light-emitting elements 260 can be respectively disposed on the plurality of bonding pads SDP.

The plurality of second electrodes CTH can be disposed on the plurality of light-emitting elements 260. The plurality of second electrodes CTH can be arranged to be spaced apart from each other in the second direction of the substrate 200.

The plurality of second electrodes CTH can extend in the first direction intersecting the second direction. The first direction can be an X-axis direction of the substrate 200, and the second direction can be a Y-axis direction of the substrate 200. However, embodiments are not limited thereto. For example, the first direction can be a transverse direction or a row direction of the substrate 200, and the second direction can be a longitudinal direction or a column direction of the substrate 200.

Each of the plurality of first electrodes AND can be referred to as a pixel electrode. Each of the plurality of second electrodes CTH can be referred to as a common electrode. However, embodiments of the present disclosure are not limited thereto. For example, each of the plurality of first electrodes AND can correspond to the first electrode CE1 of FIG. 8. In addition, each of the plurality of second electrodes CTH can correspond to the second electrode CE2 of FIG. 8.

The plurality of pixels PX can be disposed on the substrate 200. The plurality of pixels PX can be arranged so as to be spaced from each other via a spacing area. One pixel can include a plurality of sub-pixels that emit light of different colors, respectively. For example, the plurality of sub-pixels can include a first sub-pixel 260R that emits red light, a second sub-pixel 260G that emits green light, and a third sub-pixel 260B that emits blue light.

A plurality of opening areas 281 can be disposed in the spacing area defined between neighboring pixels PX. The plurality of opening areas 281 can be defined by a light blocking pattern 280 as shown in FIG. 24. The plurality of opening areas 281 can be disposed at a position corresponding to an ALS (Ambient Light System).

Referring to FIG. 24, the substrate 200 can be an insulating substrate including a plastic or polymer material having flexibility. For example, the substrate 200 can include a single layer or a multilayer structure including polyimide, polycarbonate, or polyethylene terephthalate. However, embodiments of the present disclosure are not limited thereto. The substrate 200 can be a silicon substrate or a glass substrate.

A carrier substrate 201 can be disposed on a rear surface of the substrate 200. The carrier substrate 201 can be made of a material that is relatively harder than the substrate 200 having flexibility. The carrier substrate 201 can be omitted. In addition, the carrier substrate 201 can be subsequently removed.

A plurality of chip alignment patterns 203 can be disposed on a front surface of the substrate 200 facing the rear surface. The plurality of chip alignment patterns 203 can define a position where the driving chip 210 is to be positioned. The plurality of chip alignment patterns 203 can include a metal material.

A buffer layer 205 can be disposed on the substrate 200 and the plurality of chip alignment patterns 203. The buffer layer 205 can cover the plurality of chip alignment patterns 203 to planarize steps resulting from the plurality of chip alignment patterns 203. The buffer layer 205 can be formed as a single layer or multiple layers made of an organic insulating material or an inorganic insulating material. For example, the organic insulating material can include acrylic resin or photosensitive polyimide. However, embodiments of the present disclosure are not limited thereto. The inorganic insulating material can include silicon oxide (SiOx) or silicon nitride (SiNx).

However, embodiments of the present disclosure are not limited thereto. The buffer layer 205 can include a multilayer structure in which organic insulating material layers and inorganic insulating material layers are alternately stacked on top of each other.

An adhesive layer 207 can be disposed on the buffer layer 205. The adhesive layer 207 can include an acrylic adhesive material.

A plurality of driving chips 210 can be disposed on the adhesive layer 207. The plurality of driving chips 210 can include a plurality of driving circuits to drive the plurality of light-emitting elements. Accordingly, the plurality of light-emitting elements can be driven based on the same control signal provided from the driving chip 210.

Each of the plurality of driving chips 210 can include pad electrodes 211 disposed on an upper surface thereof.

A planarization layer 220 covering the plurality of driving chips 210 can be disposed on the adhesive layer 207. The planarization layer 220 can include a first planarization layer 213 and a second planarization layer 215. A protective film 214 can be disposed between the first planarization layer 213 and the second planarization layer 215.

The first planarization layer 213 can have a thickness corresponding to a portion of a vertical dimension of a side surface of each of the plurality of driving chips 210. The first planarization layer 213 can include an organic insulating material. For example, the first planarization layer 213 can include a PAC (Photo Active Compound). However, embodiments of the present disclosure are not limited thereto.

The protective film 214 can include a first portion 214a disposed on an upper surface of the first planarization layer 213, a third portion 214c disposed on an upper edge portion of each of the plurality of driving chips 210, and a second portion 214b disposed between the first portion 214a and the third portion 214c. The second portion 214b can connect the first portion 214a and the third portion 214c to each other, and can cover a portion of the side surface of each of the plurality of driving chips 210.

The protective film 214 can enhance an adhesive force between each of the plurality of driving chips 210 and the planarization layer 220 to prevent a void from being formed between each of the plurality of driving chips 210 and the planarization layer 220. Preventing the occurrence of the void can resulting in preventing moisture or a chemical solution from penetrating into the plurality of driving chips 210 during a manufacturing process. The protective film 214 can include an inorganic insulating material. For example, the protective film 214 can include silicon nitride (SIN).

The second planarization layer 215 can be disposed on the protective film 214. The second planarization layer 215 can cover the third portion 214c of the protective film 214 and can include an opening hole defined therein exposing the pad electrode 211 of each of the plurality of driving chips 210. The second planarization layer 215 can include an organic insulating material. For example, the second planarization layer 215 can include a photoactive composite (PAC). However, embodiments of the present disclosure are not limited thereto.

A plurality of wiring patterns 223 can be disposed on the second planarization layer 215. The plurality of wiring patterns 223 and the pad electrodes 211 of the plurality of driving chips 210 can be disposed at the same vertical level. The plurality of wiring patterns 223 can be referred to as a plurality of (1-1)-th connection lines.

At least one insulating layer 225, 230, 235, and 239 covering the plurality of driving chips 210 can be disposed on the second planarization layer 215. The one or more insulating layers 225, 230, 235, and 239 can include a first insulating layer 225, a second insulating layer 230, a third insulating layer 235, and a fourth insulating layer 239. However, embodiments of the present disclosure are not limited thereto.

The first insulating layer 225 can be disposed on the second planarization layer 215 and can have each first contact hole 226 defined therein exposing each of the pad electrode 211 of each of the plurality of driving chips 210 and each of the plurality of wiring patterns 223. The second insulating layer 230 can be disposed on the first insulating layer 225 and can have a second contact hole 232 defined therein. The third insulating layer 235 can be disposed on the second insulating layer 230 and can have a third contact hole 236 defined therein. The fourth insulating layer 239 can be disposed on the third insulating layer 235, and can have a fourth contact hole 240 defined therein. The first contact hole 226, the second contact hole 232, the third contact hole 236, and the fourth contact hole 240 can be positioned so as not to overlap each other in the vertical direction. However, embodiments of the present disclosure are not limited thereto.

Each of the at least one or more insulating layers 225, 230, 235, and 239 can include a plurality of signal lines 227, 233, 237, and 241 electrically connecting the plurality of driving chips 210 and the plurality of light-emitting elements 260 to each other.

The plurality of signal lines 227, 233, 237, and 241 can include a first signal line 227, a second signal line 233, a third signal line 237, and a fourth signal line 241.

The first signal line 227 can be disposed on the first contact hole 226 of the first insulating layer 225 and can be electrically connected to the pad electrode 211 and the plurality of wiring patterns 223. The second signal line 233 can be disposed on the second contact hole 232 of the second insulating layer 230 and can be electrically connected to the first signal line 227. The third signal line 237 can be disposed on the third contact hole 236 of the third insulating layer 235 and can be electrically connected to the second signal line 233. The fourth signal line 241 can be disposed on the fourth contact hole 240 of the fourth insulating layer 239 and can be electrically connected to the third signal line 237.

The first signal line 227, the second signal line 233, the third signal line 237, and the fourth signal line 241 can be connected to each other in the vertical direction to electrically connect the plurality of driving chips 210 and the plurality of light-emitting elements 260 to each other. The fourth signal line 241 can be electrically connected to the second electrode CTH. Accordingly, the control signal provided from the plurality of driving chips 210 can be transmitted to the plurality of light-emitting elements 260 to drive the plurality of light-emitting elements 260.

While the plurality of signal lines 227, 233, 237, and 241 are formed, at least one of the plurality of alignment key patterns 101 and 103 as shown in FIG. 19 can be formed. For example, while the third signal line 237 and the fourth signal line 241 are formed, the plurality of second alignment key patterns 103 can be formed.

A plurality of bank layers 250 can be disposed on the fourth insulating layer 239. Each of the plurality of bank layers 250 can distinguish adjacent sub-pixels from each other. Each of the plurality of bank layers 250 can include an organic insulating material. For example, the organic insulating material can include polyimide (PI). However, embodiments of the present disclosure are not limited thereto.

The plurality of first electrodes AND can be disposed on the plurality of bank layers 250. Each solder pattern SDP can be disposed on each of the plurality of first electrodes AND. Each of the plurality of light-emitting elements 260 can be mounted on each solder pattern SDP and thus can be electrically connected to each of the plurality of first electrodes AND via each bonding pad.

At least one light-emitting element 260 can be disposed on each of the plurality of bank layers 250. For example, two light-emitting elements 260a and 260b emitting light of the same color can be disposed on one bank layer 250. One of the two light-emitting elements 260a and 260b can act as the main light-emitting element 260a, and the other thereof can act as the redundant light-emitting element 260b.

According to an embodiment of the present disclosure, the operation state of each light-emitting element can be inspected in a non-contact manner in the transfer process of the light-emitting element.

In addition, according to an embodiment of the present disclosure, the main light-emitting element operating normally is transferred to the panel substrate during a transfer process of the light-emitting element, based on a result of inspecting a light-emitting state thereof in a non-contact manner, while a redundant light-emitting element corresponding thereto is transferred to the panel substrate only when the main light-emitting element is defective, based on a result of inspecting a light-emitting state thereof in a non-contact manner. Thus, the display device capable of reducing the material consumption for the light-emitting elements can be realized.

In addition, according to an embodiment of the present disclosure, the material consumption in the transfer process of the light-emitting element is reduced, thereby reducing the manufacturing cost.

In addition, according to an embodiment of the present disclosure, the speed of the transfer process can be improved.

In addition, according to an embodiment of the present disclosure, a defect of the display device can be reduced by removing the defective element in the transfer process of the light-emitting element.

In addition, according to an embodiment of the present disclosure, a deterioration in the lifespan of the display device can be prevented by reducing the defect of the display device.

In addition, according to an embodiment of the present disclosure, as the defect of the display device is reduced, the power consumption of the display device can be lowered.

In addition, according to an embodiment of the present disclosure, as the defect of the light-emitting element is reduced, a long-life and low power consuming display device can be realized.

In addition, in the display device according to the present disclosure, as the defect of the light-emitting element is reduced in the process of manufacturing the display panel, the reduction of a deterioration in the lifespan of the display panel and the improvement of the quality of the display device can be implemented.

In addition, in the display device according to the present disclosure, the light-emitting element can be stably transferred, thereby improving product quality and securing product reliability.

The display device according to various aspects and embodiments of the present disclosure can be described as follows.

A first aspect of the present disclosure provides a display device comprising: a substrate including a display area and a non-display area; a driving chip disposed on the display area of the substrate; a plurality of light-emitting elements electrically connected to the driving chip, wherein the plurality of light-emitting elements and the driving chip are disposed in different layers on the display area; a pad electrode disposed on the non-display area of the substrate and electrically connected to the plurality of light-emitting elements; and a black matrix having a plurality of openings defined therein respectively at positions corresponding to the plurality of light-emitting elements, wherein the black matrix is disposed on the plurality of light-emitting elements such that the plurality of light-emitting elements are exposed through the plurality of openings, respectively, wherein an electric field is applied to each of the plurality of light-emitting elements in a non-contact manner to determine whether a current therefrom is detected through the pad electrode, wherein the opening corresponding to the light-emitting element from which no current is detected through the pad electrode is filled with the black matrix.

In accordance with some embodiments of the first aspect of the present disclosure, each of the openings is formed to correspond to each of a main light-emitting element and a redundant light-emitting element of each of the plurality of light-emitting elements.

In accordance with some embodiments of the first aspect of the present disclosure, the respective main light-emitting elements of the plurality of light-emitting elements are first transferred to a panel substrate, wherein an electric field is applied to each of the main light-emitting elements to determine whether a current therefrom is detected through the pad electrode, wherein the redundant light-emitting element corresponding to the main light-emitting element from which no current is detected through the pad electrode is transferred to the panel substrate, wherein the opening corresponding to the main light-emitting element from which no current is detected through the pad electrode is filled with the black matrix, and the main light-emitting element from which no current is detected through the pad electrode is covered with the black matrix.

In accordance with some embodiments of the first aspect of the present disclosure, an electric field is applied to each of a main light-emitting element and a redundant light-emitting element of each of the plurality of light-emitting elements to determine whether a current therefrom is detected through the pad electrode, wherein the opening corresponding to the main light-emitting element or the redundant light-emitting element from which no current is detected through the pad electrode is filled with the black matrix, and the main light-emitting element or the redundant light-emitting element from which no current is detected through the pad electrode is covered with the black matrix.

In accordance with some embodiments of the first aspect of the present disclosure, the plurality of light-emitting elements include a first light-emitting element emitting red color light, a second light-emitting element emitting green color light, and a third light-emitting element emitting blue color light.

In accordance with some embodiments of the first aspect of the present disclosure, the first light-emitting element is the main light-emitting element or the redundant light-emitting element, wherein the second light-emitting element is the main light-emitting element or the redundant light-emitting element, wherein the third light-emitting element is the main light-emitting element or the redundant light-emitting element.

In accordance with some embodiments of the first aspect of the present disclosure, the openings include a first opening corresponding to the first light-emitting element, a second opening corresponding to the second light-emitting element, and a third opening corresponding to the third light-emitting element.

In accordance with some embodiments of the first aspect of the present disclosure, the first opening corresponds to a main light-emitting element or a redundant light-emitting element of the first light-emitting element, wherein the second opening corresponds to a main light-emitting element or a redundant light-emitting element of the second light-emitting element, wherein the third opening corresponds to a main light-emitting element or a redundant light-emitting element of the third light-emitting element.

In accordance with some embodiments of the first aspect of the present disclosure, at least two of the first opening to the third opening have the same size.

In accordance with some embodiments of the first aspect of the present disclosure, the first opening and the second opening have the same area and size.

In accordance with some embodiments of the first aspect of the present disclosure, the second opening and the third opening have the same area and size.

In accordance with some embodiments of the first aspect of the present disclosure, the first opening and the third opening have the same area and size.

In accordance with some embodiments of the first aspect of the present disclosure, the first light-emitting element, the second light-emitting element, and the third light-emitting element constitute one light-emitting unit and are arranged in a horizontal direction, wherein the black matrix is disposed to fill a contact hole disposed outwardly of the first light-emitting element and a contact hole disposed outwardly of the third light-emitting element, wherein the black matrix is disposed on top of the plurality of light-emitting elements and in an area between the first light-emitting element and the second light-emitting element and an area between the second light-emitting element and the third light-emitting element.

In accordance with some embodiments of the first aspect of the present disclosure, the black matrix includes an organic insulating material containing a black pigment or a black dye added thereto.

In accordance with some embodiments of the first aspect of the present disclosure, each of the plurality of light-emitting elements is embodied as a micro light-emitting element.

In accordance with some embodiments of the first aspect of the present disclosure, the micro light-emitting element has a vertical structure.

In accordance with some embodiments of the first aspect of the present disclosure, a first electrode is disposed under each of the plurality of light-emitting elements, wherein the light-emitting element is electrically connected to the first electrode via eutectic bonding.

A second aspect of the present disclosure provides a display device comprising: a substrate including a display area and a non-display area; a driving chip disposed on the display area of the substrate; a plurality of light-emitting elements electrically connected to the driving chip, wherein the plurality of light-emitting elements are disposed on top of the driving chip in the display area; a pad electrode disposed on the non-display area of the substrate and electrically connected to the plurality of light-emitting elements; and an optical insulating layer disposed on the display area of the substrate so as to surround each of the plurality of light-emitting elements, wherein the optical insulating layer are further disposed on top of the plurality of light-emitting elements; and a black matrix disposed on the optical insulating layer and having a plurality of openings defined therein respectively at positions corresponding to the plurality of light-emitting elements, wherein an electric field is applied to each of the plurality of light-emitting elements in a non-contact manner to determine whether a current therefrom is detected through the pad electrode, wherein the opening corresponding to the light-emitting element from which no current is detected through the pad electrode is filled with the black matrix.

In accordance with some embodiments of the second aspect of the present disclosure, the display device further comprises: a first electrode disposed under each of the plurality of light-emitting elements and electrically connected to each of the plurality of light-emitting elements; and a second electrode disposed on the plurality of light-emitting elements and parts of the optical insulating layer and electrically connected to the plurality of light-emitting elements.

In accordance with some embodiments of the second aspect of the present disclosure, the optical insulating layer includes: a first optical layer disposed on the display area of the substrate so as to surround each of the plurality of light-emitting elements; a second optical layer disposed on the display area of the substrate so as to surround the first optical layer; and a third optical layer disposed on the display area of the substrate and disposed on the second electrode.

In accordance with some embodiments of the second aspect of the present disclosure, the second electrode continuously extends on and along the plurality of light-emitting elements and parts of the optical insulating layer.

In accordance with some embodiments of the second aspect of the present disclosure, the second electrode is disposed to overlap the first optical layer and to cover a flat upper surface of an outer portion of the first optical layer.

In accordance with some embodiments of the second aspect of the present disclosure, the second electrode is commonly connected to the plurality of light-emitting elements.

In accordance with some embodiments of the second aspect of the present disclosure, the third optical layer is disposed to overlap the plurality of light-emitting elements and the first optical layer.

In accordance with some embodiments of the second aspect of the present disclosure, the first electrode is composed of a plurality of conductive layers, wherein the plurality of conductive layers include: a first conductive layer disposed on a bank; a second conductive layer disposed on the first conductive layer; a third conductive layer disposed on the second conductive layer; and a fourth conductive layer disposed on the third conductive layer.

In accordance with some embodiments of the second aspect of the present disclosure, the light-emitting element has a vertical structure.

In accordance with some embodiments of the second aspect of the present disclosure, the light-emitting element is electrically connected to the first electrode via eutectic bonding.

In accordance with some embodiments of the second aspect of the present disclosure, each of the plurality of light-emitting elements has a groove defined in a center area of a bottom thereof, wherein a solder pattern fills the groove and protrudes downwardly beyond a bottom surface of each of the plurality of light-emitting elements such that a protruding portion of the solder pattern contacts the first electrode.

In accordance with some embodiments of the second aspect of the present disclosure, each of the plurality of light-emitting elements includes: an anode electrode disposed on the solder pattern; a first semiconductor layer disposed on the anode electrode; an active layer disposed on the first semiconductor layer; a second semiconductor layer disposed on the active layer; a cathode electrode disposed on the second semiconductor layer; and an encapsulation film disposed on at least a portion of each of the first semiconductor layer, the active layer, the second semiconductor layer, the anode electrode, and the cathode electrode.

In accordance with some embodiments of the second aspect of the present disclosure, a portion of the black matrix is disposed in a contact hole of the optical insulating layer via which the second electrode and the contact electrode are connected to each other.

In accordance with some embodiments of the second aspect of the present disclosure, the second electrode is used as a touch electrode instead of forming a separate touch electrode

Although some embodiments of the present disclosure have been described above with reference to the accompanying drawings, the present disclosure may not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A display device comprising:
a substrate including a display area and a non-display area;
a driving chip disposed on the substrate in the display area;
a plurality of light-emitting elements electrically connected to the driving chip, wherein the plurality of light-emitting elements and the driving chip are disposed in different layers in the display area;
a pad electrode disposed in the non-display area of the substrate and electrically connected to the plurality of light-emitting elements; and
a black matrix having a plurality of openings defined therein respectively at positions corresponding to the plurality of light-emitting elements, wherein the black matrix is disposed on the plurality of light-emitting elements so that the plurality of light-emitting elements are exposed through the plurality of openings, respectively,
wherein an electric field is applied to each of the plurality of light-emitting elements in a non-contact manner to determine whether a current therefrom is detected through the pad electrode, and
wherein when no current is detected from one of the plurality of light-emitting elements through the pad electrode, one of the plurality of openings corresponding to the one of the plurality of light-emitting elements from which no current is detected through the pad electrode is filled with the black matrix.

2. The display device of claim 1, wherein each of the plurality of openings is disposed to correspond to each of a main light-emitting element and a redundant light-emitting element of one of the plurality of light-emitting elements.

3. The display device of claim 2, wherein the main light-emitting elements of the plurality of light-emitting elements are first transferred to a panel substrate,
wherein an electric field is applied to each of the main light-emitting elements to determine whether a current therefrom is detected through the pad electrode,
wherein the redundant light-emitting element corresponding to the main light-emitting element from which no current is detected through the pad electrode is transferred to the panel substrate, and
wherein the opening corresponding to the main light-emitting element from which no current is detected through the pad electrode is filled with the black matrix, and the main light-emitting element from which no current is detected through the pad electrode is covered with the black matrix.

4. The display device of claim 2, wherein an electric field is applied to each of a main light-emitting element and a redundant light-emitting element of each of the plurality of light-emitting elements to determine whether a current therefrom is detected through the pad electrode,
wherein the opening corresponding to the main light-emitting element or the redundant light-emitting element from which no current is detected through the pad electrode is filled with the black matrix, and the main light-emitting element or the redundant light-emitting element from which no current is detected through the pad electrode is covered with the black matrix.

5. The display device of claim 1, wherein the plurality of light-emitting elements include a first light-emitting element configured to emit red color light, a second light-emitting element configured to emit green color light, and a third light-emitting element configured to emit blue color light.

6. The display device of claim 5, wherein the first light-emitting element is a main light-emitting element or a redundant light-emitting element,
wherein the second light-emitting element is a main light-emitting element or a redundant light-emitting element, and
wherein the third light-emitting element is a main light-emitting element or a redundant light-emitting element.

7. The display device of claim 5, wherein the plurality of openings include a first opening corresponding to the first light-emitting element, a second opening corresponding to the second light-emitting element, and a third opening corresponding to the third light-emitting element.

8. The display device of claim 7, wherein the first opening corresponds to a main light-emitting element or a redundant light-emitting element of the first light-emitting element,
wherein the second opening corresponds to a main light-emitting element or a redundant light-emitting element of the second light-emitting element, and
wherein the third opening corresponds to a main light-emitting element or a redundant light-emitting element of the third light-emitting element.

9. The display device of claim 7, wherein at least two of the first opening, the second opening and the third opening have a same size.

10. The display device of claim 7, wherein the first opening and the second opening have a same area and a same size, or
wherein the second opening and the third opening have a same area and a same size, or
wherein the first opening and the third opening have a same area and a same size.

11. The display device of claim 5, wherein the first light-emitting element, the second light-emitting element, and the third light-emitting element constitute one light-emitting unit and are arranged in a horizontal direction,
wherein the black matrix is disposed to fill a contact hole disposed outwardly of the first light-emitting element and a contact hole disposed outwardly of the third light-emitting element, and
wherein the black matrix is disposed on top of the plurality of light-emitting elements and in an area between the first light-emitting element and the second light-emitting element and in an area between the second light-emitting element and the third light-emitting element.

12. The display device of claim 1, wherein the black matrix includes an organic insulating material containing a black pigment or a black dye added thereto.

13. The display device of claim 1, wherein each of the plurality of light-emitting elements is embodied as a micro light-emitting element.

14. The display device of claim 13, wherein the micro light-emitting element has a vertical structure.

15. The display device of claim 1, wherein a first electrode is disposed under each of the plurality of light-emitting elements, and
wherein each of the plurality of light-emitting elements is electrically connected to the corresponding first electrode by eutectic bonding.

16. A display device comprising:
a substrate including a display area and a non-display area;
a driving chip disposed on the substrate in the display area;
a plurality of light-emitting elements electrically connected to the driving chip, wherein the plurality of light-emitting elements are disposed on top of the driving chip in the display area;
a pad electrode disposed in the non-display area of the substrate and electrically connected to the plurality of light-emitting elements;
an optical insulating layer disposed in the display area of the substrate so as to surround at least one of the plurality of light-emitting elements, wherein the optical insulating layer is further disposed on the plurality of light-emitting elements; and
a black matrix disposed on the optical insulating layer and having a plurality of openings disposed therein respectively at positions corresponding to the plurality of light-emitting elements,
wherein an electric field is applied to each of the plurality of light-emitting elements in a non-contact manner to determine whether a current therefrom is detected through the pad electrode, and
wherein when no current is detected from one of the plurality of light-emitting elements through the pad electrode, one of the plurality of openings corresponding to the one of the plurality of light-emitting elements from which no current is detected through the pad electrode is filled with the black matrix.

17. The display device of claim 16, wherein the display device further comprises:
a first electrode disposed under each of the plurality of light-emitting elements and electrically connected to a corresponding one of the plurality of light-emitting elements; and
a second electrode disposed on the plurality of light-emitting elements and parts of the optical insulating layer and electrically connected to the plurality of light-emitting elements.

18. The display device of claim 17, wherein the optical insulating layer includes:
a first optical layer disposed in the display area of the substrate so as to surround at least one of the plurality of light-emitting elements;
a second optical layer disposed in the display area of the substrate so as to surround the first optical layer; and
a third optical layer disposed on the second electrode in the display area of the substrate.

19. The display device of claim 17, wherein the second electrode continuously extends on and along the plurality of light-emitting elements and parts of the optical insulating layer.

20. The display device of claim 18, wherein the second electrode is disposed to overlap the first optical layer and to cover a flat upper surface of an outer portion of the first optical layer.
